(19) United States
(12) Patent Application Publication
(10) Pub. No.: US 2015/0325328 A1
(43) Pub. Date: Nov. 12, 2015

(54) GROUP IV NANOCRYSTALS HAVING A SURFACE SUBSTANTIALLY FREE OF OXYGEN

(71) Applicant: REGENTS OF THE UNIVERSITY OF MINNESOTA, Minneapolis, MN (US)

(72) Inventors: Uwe Richard Kortshagen, Roseville, MN (US); Nicolaas Johannes Kramer, Minneapolis, MN (US); Lance Michael Wheeler, Denver, CO (US); Ting Chen, Minneapolis, MN (US)

(21) Appl. No.: 14/690,970

(22) Filed: Apr. 20, 2015

Related U.S. Application Data
(60) Provisional application No. 61/981,271, filed on Apr. 18, 2014.

(51) Int. Cl. H01B 1/04; C09D 11/52; H01L 21/02; B01J 19/08

(52) U.S. Cl. CPC H01B 1/04; B01J 19/088; C09D 11/52; H01L 21/02628; B01J 2219/0809; B01J 2219/0898

(57) ABSTRACT

Group IV nanocrystals having a surface substantially free of oxygen, and methods of making such Group IV nanocrystals, are disclosed herein. Group IV nanocrystals having a surface substantially free of oxygen can advantageously be used to prepare nanocrystal inks and films.

This application claims the benefit of U.S. Provisional Application No. 61/981,271, filed Apr. 18, 2014, which is incorporated herein by reference in its entirety.

### GOVERNMENT SUPPORT

This invention was made with government support under DE-AC52-06NA25396 awarded by the Department of Energy; DE-SC0001939 awarded by the Department of Energy and DMR-0819885 awarded by the National Science Foundation. The government has certain rights in the invention.

### BACKGROUND

Size-tunable optical properties and the ability to process thin films using scalable, cost-efficient printing techniques have long made colloidal nanocrystals (NCs) an attractive candidate for next-generation optoelectronics. Much of the recent progress in this direction hinges on the ability to manipulate the NC surface. Conventional solution synthesis yields NCs with ligands bound to a metal surface atom through a labile acid-base complex. The electrically-insulating native ligands are thus routinely exchanged during, or after, film assembly to produce conductive NC arrays for devices such solar cells, light-emitting devices, transistors, photodetectors, and thermoelectrics. Solution-phase ligand exchange using “Ionic ligands” is a breakthrough that enables NCs to be deposited directly from solution into conductive thin films. Just as surface manipulation has launched metal-based NCs to the forefront of optoelectronic technology, it is the inability to do so with the covalent surface of group IV NCs that has greatly hindered progress.

There is a continuing need for colloidal NCs having improved properties and improved methods of making such colloidal NCs.

### SUMMARY

In one aspect, the present disclosure provides a Group IV nanocrystal having a surface substantially free of oxygen. In certain embodiments the surface of the nanocrystal is substantially free of organic ligands and surfactants. In certain embodiments, the Group IV element is Si, Ge, or a combination thereof. In some embodiments, the surface of the nanocrystal further includes P and/or B atoms. In certain embodiments, the nanocrystal further comprises activated dopants in the silicon core and the nanocrystal has an infrared surface plasmon absorption.

In another aspect, the present disclosure provides a method of making a Group IV nanocrystal. The method includes: providing a Group IV monomer and a phosphorus and/or boron precursor to a plasma reactor under conditions effective to produce a Group IV nanocrystal, wherein the surface of the nanocrystal is substantially free of oxygen.

In another aspect, the present disclosure provides a nanocrystal ink including a colloidal dispersion in a solvent of Group IV nanocrystals as described herein. The solvent can be aqueous or non-aqueous. In certain embodiments, the nanocrystals are substantially non-agglomerated.

In another aspect, the present disclosure provides a method of preparing a nanocrystal ink. The method includes combining a plurality of Group IV nanocrystals as described herein with an organic solvent under conditions effective to form a colloidal dispersion of the nanocrystals.

In another aspect, the present disclosure provides a nanocrystal film including a plurality of Group IV nanocrystals as described herein.

In another aspect, the present disclosure provides a method of making a nanocrystal film. The method includes solution coating a nanocrystal ink as described herein.

In another aspect, the present disclosure provides a semiconductor device including a nanocrystal film as described herein. Exemplary semiconductor devices include solar cells, transistors, photodetectors, and light emitting diodes.

Group IV nanocrystals having a surface substantially free of oxygen can advantageously be used to prepare nanocrystal inks having relatively high concentrations of the nanocrystals in a wide variety of solvents. The nanocrystal inks can be used to prepare nanocrystal films that are electrically conducting or semiconducting. Such nanocrystal films can be used as active layers in devices that include solar cells, transistors, photodetectors, and light emitting diodes. Boron atoms on the surface of the nanocrystals can reduce the oxidation rate, which in some embodiments can enable handling of the nanocrystals outside of an air-free environment. Furthermore, in some embodiments, the nanocrystals may not undergo significant unwanted oxidation in solution.

### Definitions

As used herein, a surface that is “substantially free of oxygen” means that the surface contains less than 25 atom % oxygen atoms, preferably less than 20 atom % oxygen atoms, more preferably less than 5 atom % oxygen atoms, and most preferably no oxygen atoms detectable by X-Ray Photoelectron Spectroscopy, Energy-Dispersive X-Ray Spectroscopy, or Fourier Transform Infrared Spectroscopy. In some embodiments, the nanocrystal is non-oxidized and/or substantially free of oxygen.

The terms “comprises” and variations thereof do not have a limiting meaning where these terms appear in the description and claims.

As used herein, “a,” “an,” “the,” “at least one,” and “one or more” are used interchangeably.

Also herein, the recitations of numerical ranges by endpoints include all numbers subsumed within that range (e.g., 1 to 5 includes 1, 1.5, 2, 2.75, 3, 3.80, 4, 5, etc.).

The above brief description of various embodiments of the present disclosure is not intended to describe each embodiment or every implementation of the present disclosure. Rather, a more complete understanding of the disclosure will become apparent and appreciated by reference to the following description and claims in view of the accompanying drawings. Further, it is to be understood that other embodiments may be utilized and structural changes may be made without departing from the scope of the present disclosure.

### BRIEF DESCRIPTION OF THE DRAWINGS

FIG. 1 illustrates (a) a cartoon representation of the plasma synthesis method used to produce Si NCs with Lewis acidic B(III) groups at the surface; (b) XPS B1s spectrum of Si NCs as they are produced from the plasma reaction, wherein surface B(III) accounts for approximately 60% of the boron in the sample; (c) FTIR spectra of Si NCs synthesized from SiH₄ only, from SiH₄ and approximately 10 atomic percent boron, and Si NC sample produced from 10 atomic percent boron after a brief exposure to air; (d) XPS B1s spectrum of Si NCs after binding an oleylamine ligand to the B(III) surface groups; (e) photographs of Si NCs stable in hexane with an olylamine ligand; and (f) (e) and photographs of Si NCs with an olylamine ligand in DMSO (f).

FIG. 2 illustrates the effects of electrolyte on colloidal stability showing (a) ζ-potential as a function of electrolyte (KI) concentration; and (b) DLS spectra at electrolyte concentrations corresponding to (a).

FIG. 3 is an illustration of an exemplary stability model analysis showing net interaction potential normalized by k_{B}T as a function of inter particle spacing, with (a) calculation considering the sum of Van der Waals attraction and electrical double layer repulsions for material systems with different Hamaker constants; (b) calculation considering the sum of Van der Waals attraction and electrical double layer repulsions for gold nanocrystals in water; (c,d) calculations considering the sum of Van der Waals attraction, electrical double layer repulsions, and solvation potential for Si NCs in DMSO at the conditions observed in FIG. 2 for λ=D_{DMSO} (c) and λ=D_{DMSO} (d). All calculations are for 8 nm diameter NCs in a 0.01 M 1:1 (z=1) electrolyte. Other relevant parameters are included in each plot.

FIG. 4 is an illustration of the impact of acid-base interactions on colloidal stability, including (a) a schematic illustrating inter particle forces and molecular interactions that give rise to solvate interaction in the form of a molecular orbital diagram; and (b) maximum achievable concentration (gray bars) for a variety of solvents with different relative permitivities and basicities as evaluated by the SbCl₅ affinity scale (−ΔH_{SbCl}_{₅}). Numbers above each bar is the maximum achievable concentration in mg ml⁻¹.

FIG. 5 illustrates exemplary co-solvent effects on colloidal stability. including (a) a photograph of Si NCs in a variety of solvent combinations to illustrate the importance of the ΔG_{AB} parameter on colloidal stability of NCs; (b) FTIR spectra for films of Si NCs cast from NMP/water mixture of varying volume fractions, wherein spectra are normalized and offset for clarity; (c) FTIR spectra of Si NC film cast from a solution of NMP with 10% water by volume before and after vacuum-treating the sample, wherein spectra are not normalized but are offset for clarity; and (d) FTIR spectra of v(C═O) of NMP taken as a function of time as NMP evaporates from an Si NC film.

FIG. 6 illustrates an exemplary IR Spectrum of 10%-boron doped nanoparticles. The lack of a silicon-oxide feature indicates an oxide free surface.

FIG. 7 illustrates an exemplary FTIR Spectrum of phosphorus doped and codoped nanoparticles. These particles exhibit plasmonic features.

FIG. 8 illustrates an exemplary SEM cross-section image of a spray coated film of boron-doped nanoparticles.

FIG. 9 illustrates an exemplary SEM cross-section image of a spray coated film of boron-doped nanoparticles showing a uniform film with no cracks.

FIG. 10 illustrates an exemplary SEM top-view image of a spray coated film of boron-doped nanoparticles on flexible polyimide substrates (available under the trade designation KAPTON from DuPont) showing a uniform film with no cracks.

FIG. 11 illustrates an exemplary SEM top-view image of a spray coated film of boron-doped nanoparticles on flexible polyimide substrates (available under the trade designation KAPTON from DuPont) showing a uniform film with no cracks.

FIG. 12 illustrates an exemplary TEM image of 8 nm crystalline boron-doped nanocrystals showing a monodisperse size distribution. There is no significant oxide shell visible.

FIG. 13 illustrates an exemplary TEM image of 12 nm crystalline boron-doped nanocrystals showing a monodisperse size distribution. There is no significant oxide shell visible.

FIG. 14 illustrates an exemplary schematic of the plasma reactor which is used to produce boron or codoped nanocrystals.

FIG. 15 illustrates an exemplary FTIR spectra comparing the oxidation rate of boron-doped and undoped nanocrystals. The boron-doped nanocrystals oxidize significantly slower as is determined by the silicon-oxide feature in the spectra.

FIG. 16 illustrates an exemplary XRD Spectra of boron-doped nanocrystals with two sizes (8 nm and 12 nm). The spectra show fully crystalline samples.

FIG. 17 illustrates an exemplary Raman spectrum of a boron-doped nanocrystal. The spectrum shows a fully crystalline sample.

FIG. 18 illustrates an exemplary image that shows two samples of Ge NCs and SiGe NCs in dimethyl sulfoxide solvent.

FIG. 19 illustrates exemplary images that show four samples of SiGe NC inks with different concentrations in dimethylsulfoxide (DMF).

FIG. 20 illustrates an exemplary transmission spectrum for SiGe NCs in solution.

FIG. 21 illustrates an exemplary FTIR spectra of as-produced (a) phosphorus-doped and (b) boron-doped silicon nanocrystals with increasing fractional doping flow rates, wherein for phosphorus-doped Si NCs a plasmon resonance emerges for sufficiently high doping concentrations, and wherein a plasmon resonance is not visible for boron-doped Si NCs, even at high doping levels, however dopant surface atoms can be observed as well as silicon hydride peaks; (c) development of the FTIR spectra during low-temperature air-free annealing of phosphorus and boron-doped Si NCs, wherein as a result of the annealing the plasmon blue-shifts for phosphorus-doped Si NCs, and wherein for boron-doped Si NCs, the annealing treatment is able to generate additional free carriers, leading to a plasmon resonance to develop; (d) effect of oxidation of phosphorus-doped and boron-doped Si NCs in air as a function of time, wherein opposite behavior is observed, with the plasmon resonance disappearing for phosphorus-doped Si NCs while a plasmon resonance appears and blue-shifts during oxidation for boron-doped Si NCs; and (e,f) schematic overview of FIGS. 21(a)-21(d) for as-produced and post-synthesis treated boron-doped and phosphorus-doped Si NCs.

FIG. 22 illustrates an exemplary Electron Paramagnetic Resonance spectra for phosphorus-doped, boron-doped and intrinsic Si NCs. Spectra are shown for as-deposited, annealed, and oxidized NCs. The spectrum for boron-doped NCs has been magnified by a factor of 5 for clarity.

FIG. 23 illustrates an exemplary X-ray Photoelectron Spectroscopy (XPS) spectra for as-produced phosphorus doped and boron-doped silicon NCs. The phosphorus spectrum can be deconvolved into two peaks. The peak at 130 eV corresponds to phosphorus bonded to phosphorus or silicon, while the broad peak at 135 eV is a result of oxidized phosphorus. For boron a broad peak at 185 eV originates from trivalent boron while the higher energy peaks correspond to tetravalent boron bonded to silicon, oxygen, or nitrogen.

FIG. 24 illustrates an exemplary (a) FTIR spectra of as-produced, oxidized and subsequently annealed at 200° C., phosphorus-doped and boron-doped silicon nanocrystals, wherein while the plasmon resonance is removed after oxidation, an annealing treatment is able to bring the plasmon resonance back; (b) development of the plasmon resonance for as-produced and subsequent oxidized and etched phosphorus-doped and boron-doped Si NCs, wherein the FTIR spectra show the difference in plasmonic behavior during oxidation and etching; (c) development of the plasmon resonance for phosphorus-doped Si NCs after oxidation, subsequent annealing followed by re-oxidation for 1, 2, 3, and 4 days; (d) EPR spectra for phosphorus-doped Si NCs, wherein a distinct difference is observed between annealed and (re-)oxidized NCs, agreeing with the FTIR spectra of (c); and (e,f) a schematic overview of FIGS. 24a-24b for an oxidized, etched and annealed boron-doped and phosphorus-doped Si NCs.

### DETAILED DESCRIPTION OF ILLUSTRATIVE EMBODIMENTS

The Group IV nanocrystals disclosed herein have surfaces that are substantially free of oxygen. In certain embodiments the surfaces of the nanocrystals are substantially free of organic ligands and surfactants. In certain embodiments, the Group IV element is Si, Ge, or a combination thereof. In some embodiments, the surfaces of the nanocrystals further include P and/or B atoms. In certain embodiments, the nanocrystal further comprises activated dopants (e.g., P and/or B atoms) in the silicon core and the nanocrystal has an infrared surface plasmon absorption.

For embodiments in which the surface of the nanocrystal includes P atoms, the surface can include from 0 atom % to 100 atom % P atoms. In some embodiments, the surface can include from 1 atom % to 60 atom % P atoms, and in certain embodiments, the surface can include from 10 atom % to 30 atom % P atoms. In some embodiments, the nanocrystal further includes P atoms in the silicon core.

For embodiments in which the surface of the nanocrystal includes B atoms, the surface can include from 0 atom % to 100 atom % B atoms. In some embodiments, the surface can include from 1 atom % to 30 atom % B atoms, and in certain embodiments, the surface can include from 5 atom % to 15 atom % B atoms. In some embodiments, the nanocrystal further includes B atoms in the silicon core.

In another aspect, the present disclosure provides a method of making a Group IV nanocrystal. The method includes: providing a Group IV monomer and a phosphorus and/or boron precursor to a plasma reactor under conditions effective to produce a Group IV nanocrystal, wherein the surface of the nanocrystal is substantially free of oxygen. In some embodiments, providing a phosphorus and/or boron precursor to the plasma reactor includes etching a phosphorus and/or boron-coated wall during synthesis.

A wide variety of plasma reactors can be used to make Group IV nanocrystals as disclosed herein. Useful plasma reactors and conditions effective to make nanocrystals are disclosed, for example, in U.S. Pat. No. 7,446,335 B2 (Kortshagen et al.) and U.S. Patent Application Publication No. 2013/0285007 A1 (Wheeler et al.).

For example, the plasma reactor can have a plasma reactor chamber with a source of a continuous gas flow through the plasma reactor chamber. Typically the plasma reactor has at least two electrodes, and a high frequency voltage source coupled to at least one of the two electrodes configured to apply a high voltage capable of generating a radiofrequency plasma in the presence of a precursor gas. In some embodiments, the precursor gas can include one or more Group IV monomers, and optionally a phosphorus precursor and/or a boron precursor. The optional phosphorus and/or boron precursors added to the radiofrequency plasma during synthesis of the nanocrystals can be incorporated within the nanocrystals (i.e., doping) and/or can modify the surface of the nanocrystals. In certain embodiments, the nanocrystals formed are substantially non-agglomerated. The formed nanocrystals can be carried out of the reactor through the outlet in a continuous fashion.

In another aspect, the present disclosure provides a nanocrystal ink including a colloidal dispersion in a solvent of Group IV nanocrystals as described herein. The solvent can be aqueous or non-aqueous. In certain embodiments, the nanocrystals are substantially non-agglomerated.

In some embodiments, the concentration of Group IV nanocrystals in the ink can be 1 microgram per milliliter to 1 gram per milliliter. In certain embodiments, the concentration of Group IV nanocrystals in the ink can be 10 microgram per milliliter to 200 milligram per milliliter. In other certain embodiments, the concentration of Group IV nanocrystals in the ink can be 100 microgram per milliliter to 50 milligram per milliliter.

In certain embodiments, the solvent can include at least one organic solvent that is a dipolar, organic solvent having a hard donor group, without a strongly acidic site, and does not chemically react with the nanocrystal surface. In some embodiments, the at least one organic solvent has a largest dimension of at most 1.5 nm. In certain embodiments, the solvent further includes water.

Exemplary organic solvents include dialkyl sulfoxides, N-substituted pyrrolidinones, N,N-disubstituted amides, nitriles, ketones, alcohols, amines, halogenated aromatics, esters, and combinations thereof. In certain embodiments, the at least one organic solvent can be one or more of dimethylsulfoxide, dimethylacetamide, N-methylpyrrolidinone, propylene carbonate, 1,2-dichlorobenzene, methyl alkyl ketones, N,N-dimethylformamide (DMF), and benzonitrile.

In another aspect, the present disclosure provides a method of preparing a nanocrystal ink. The method includes combining a plurality of Group IV nanocrystals as described herein with an organic solvent under conditions effective to form a colloidal dispersion of the nanocrystals. Typical conditions effective to prepare the nanocrystal ink include gentle mixing or sonication at room temperature.

In another aspect, the present disclosure provides a nanocrystal film including a plurality of Group IV nanocrystals as described herein.

In another aspect, the present disclosure provides a method of making a nanocrystal film. The method includes solution coating a nanocrystal ink as described herein. Exemplary solution coating methods can include one or more of drop casting, spin coating, dip coating, meyer rod coating, doctor blade coating, inkjet printing, screen printing, contact printing, and spray coating. In some embodiments, the method of making the nanocrystal film can further include allowing the solvent to evaporate at a temperature of at most 250° C.

In another aspect, the present disclosure provides a semiconductor device including a nanocrystal film as described herein. Exemplary semiconductor devices include solar cells, transistors, photodetectors, and light emitting diodes. See, for example, Gresback et al., ACS Nano, 2014, 8(6):5650-5656.

The present invention is illustrated by the following examples. It is to be understood that the particular examples, materials, amounts, and procedures are to be interpreted broadly in accordance with the scope and spirit of the invention as set forth herein.

### EXAMPLES

### Example 1

In this work, it was demonstrated that a Lewis acidic boron surface chemistry for gas-phase synthesized Si NCs can provide the same solution-phase versatility as the metal-based NC surface. This represents an immense step toward an abundant, non-toxic alternative to Pb and Cd-based NCs. Additionally, these Si NCs are uniquely suited for investigating the mechanism of colloidal stability that has been observed after NCs are exchanged for “ionic ligands.” It was found that the colloidal forces needed for stability are contrary to the mechanism that has been previously invoked and an alternative model for achieving colloidal stability in any NC system is proposed. Using this model, stable Si NC colloids in media that runs the gamut from hexane to water were demonstrated.

Close to three decades of research has launched colloidal NCs from the laboratory to a viable optoelectronic technology platform. As the industry grows, so does the need for non-toxic alternatives to Cd and Pb-based NCs. Nonthermal plasmas have emerged as the most prolific synthetic method for high-quality group IV NCs (Liu et al., Nano Letters, 13(4):1578-1587, 2013). However, the resulting nano powder remains difficult to process into thin films without strongly-bound covalently bonding an alkane ligand to the NC surface to form a stable colloid in nonpolar solvents (Kortshagen, Journal of Physics D: Applied Physics, 42(11):113001, May 2009). The strength of the Si—C bond make ligand exchange strategies found in the metal-based NC literature impractical. Encouraging results have emerged recently that circumvent the need of a ligand. Plasma-synthesized Si NCs (Anthony et al., Advanced Functional Materials, 21(21):4042-4046, August 2011) and Ge NCs (Wheeler et al., Nature Communications, 4, 2013) terminated with chlorine have shown colloidal stability in relatively polar solvents. The electron-withdrawing nature of chlorine renders Si or Ge NC surface atoms Lewis acidic and able to engage in a “hypervalent” three-center two-electron bond with Lewis basic solvent molecules. This hypervalent interaction was found to be relevant to stability.

A more direct strategy to produce a Lewis acidic surface chemistry with boron is utilized in this work. A boron source (B₂H₆) is incorporated with the silicon source (SiH₄) during plasma synthesis (FIG. 1a) to produce monodisperse (within approximately 15%) 8 or 12 nm Si NCs. FIG. 1b shows an XPS spectrum of the B(1s) peak in the as-synthesized Si NCs. The spectrum is deconvolved into 4 peaks. The broad peak centered at a low binding energy of approximately 185 eV is unmistakably trivalent state (B(III)) (Holman et al., Nano Letters, 11(5):2133-2136, May 2011). The sharpest peak at approximately 188 eV corresponds to tetravalent boron (B(IV)) that is incorporated into the NC. The two remaining higher binding energy peaks are also boron in the B(IV) state, but they are bonded to an electronegative atom in addition to Si. This is likely due to oxidation of surface boron upon exposure to ambient oxygen and water during sample transfer. This is validated by the Fourier transform infrared (FTIR) spectrum in FIG. 1c, as the peak corresponding to v(Si—B—O) increases in relative intensity after brief air exposure.

Peak integration of the XPS spectrum reveals approximately 60% of the boron exists in the B(III) state. Since TEM and X-ray diffraction show highly crystalline NCs, the B(III) must exist on the Si NC surface. First principle calculations show the B atoms to energetically favor surface segregation to the Si NC surface in a trivalent coordination as opposed to substitutional incorporation (Kazahaya et al., Japanese Journal of Applied Physics, 25(1):L75-L77, 1986). In this state, boron has only three valence electrons, while there are four valence orbitals, 2s, 2pₓ, 2p_{y}, and 2p_{z}. The extra vacant valence orbital make boron a Lewis acid in the classical sense. As such, oleylamine and dioctylamine ligand coordination to the boron surface sites was demonstrated. This is shown in FIG. 1d where the B(III) component of the spectrum has been dramatically reduced. The N1s peak also validates coordination through the amine group of the ligand. After binding ligands to the surface, they can be dispersed in the nonpolar solvents typically used in these systems such as hexane or toluene. FIG. 1e shows a photograph of a biphasic solution of oleylamine-capped Si NCs dispersed in hexane over dimethylsulfoxide (DMSO).

It should be noted that the oleylamine capped Si NCs are dramatically different from what has been previously demonstrated with covalent Si—C—R or Si—O—R linkages. Since the ligands described in this work are bound through an acid-base complex, these ligands are presumably exchangeable using the well-developed techniques in the metal-based NC literature. This also opens up the possibility of shell growth using similarly well-established techniques, which has never been shown for group IV NCs and is currently under investigation.

The remainder of this disclosure will focus on the result captured by the photograph in FIG. 1f. Si NC nanopowder obtained from a SiH₄/B₂H₆ reaction containing at least approximately 4 atomic percent boron will disperse into a stable colloid by simply adding solvent and gently agitating. FIG. 1f shows a biphasic solution of Si NCs stable in DMSO. The importance of a Lewis acidic surface has been previously disclosed (Anthony et al., Advanced Functional Materials, 21(21):4042-4046, August 2011). Surface boron has also previously been recognized as important by Sugimoto et al., but its role in Si NC stability was misunderstood as “inorganic atomic ligands” (Pi et al., The Journal of Physical Chemistry C, 115(20):9838-9843, 2011). The boron at the Si NC surface plays the same role as a metal atom at the surface of a metal chalcogenide NC as acidic binding site for Lewis basic heteroatoms of ligands (or solvent); boron itself is not a ligand.

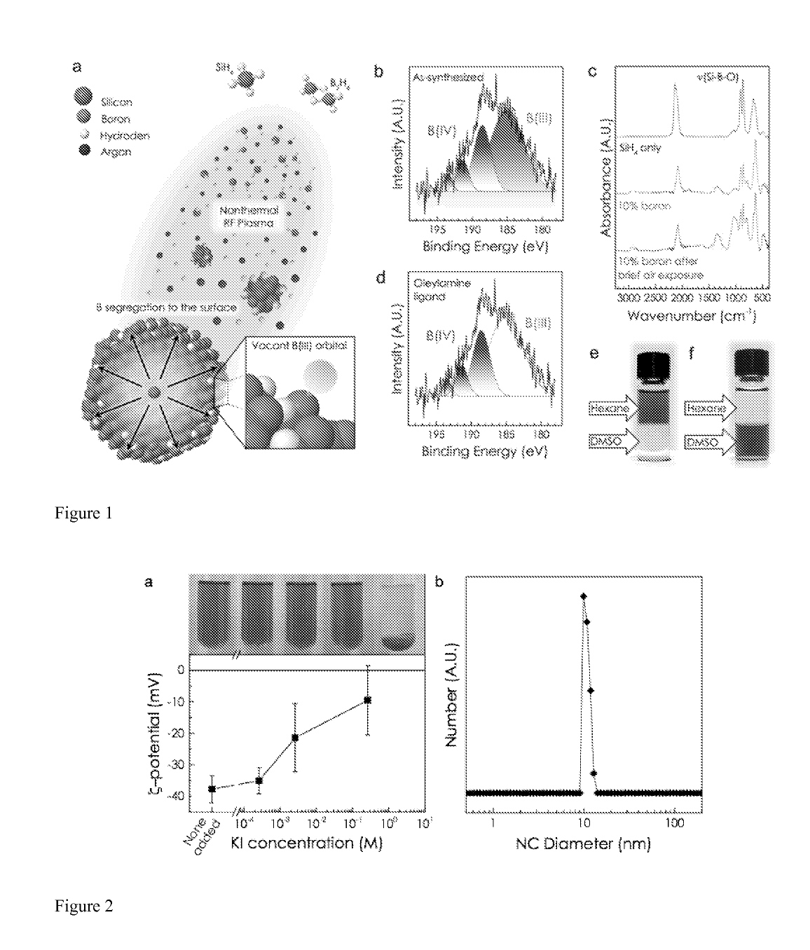

The Si NCs will form extremely dense (>50 mg/ml) solutions when dispersed into strong Lewis basic solvents such DMSO, N-methylpyrrolidone (NMP), or dimethylacetamide (DMA). This stability was investigated by first turning to conventional colloid characterization methods. FIG. 2a shows ζ-potential as a function of electrolyte concentration, potassium iodide (KI) in DMSO. The Si NCs dispersed in neat DMSO (no electrolyte intentionally added) indeed acquire a charge resulting in a zeta potential of −37±4 mV. Upon adding more electrolyte to the Si NC solution, the zeta potential is monotonically reduced to −10±10 mV, but the Si NCs remain stable up to electrolyte concentrations as high as 0.25 M until they agglomerate and crash out of solution. FIG. 2b shows the dynamic light scattering (DLS) spectrum at each KI concentration. The NCs only slightly increase in mean size with increasing electrolyte.

In light of these observations, one can now step back from the Si NC system and consider the general observations for the NC community working with “inorganic ligands.” After measuring a ζ-potential, the prevailing opinion in the colloidal NC literature is to conclude colloidal stability is due to repulsions by an electrical double layer as described by DLVO theory. This opinion deserves scrutiny. DLVO theory can be found in many textbooks. Briefly, DLVO is a mean field theory that considers the sum of two opposing potentials of particles approaching each other, Φₙₑₜ=Φ_{VdW}+Φ_{EDL} where

$${φ}_{VdW} = - \frac{{A}_{212} α}{12 d}$$

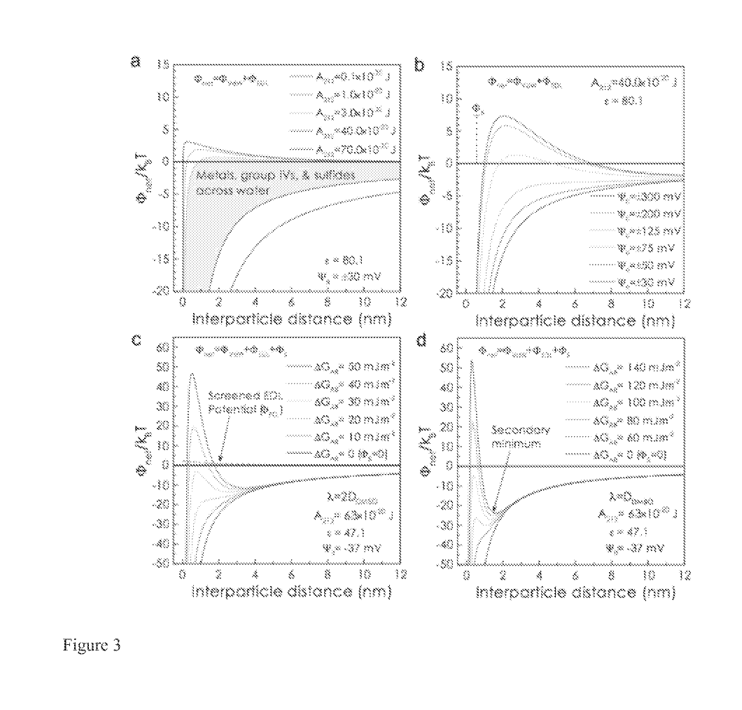

is the non-retarded Van der Waals potential. A₂₁₂ is the Hamaker constant, a NC material and medium dependent constant. For this work, A₂₁₂ values are taken from the literature or calculated using the Lifshitz approximations. a is the NC diameter, and d is the inter-NC distance. The typical form of the repulsive electrical double layer potential was considered where a Poisson-Boltzmann distribution and the Derjaguin approximation for spherical particles was assumed:

$${φ}_{EDL} = \frac{64 π {ak}_{B} {Tn}_{l}}{{κ}^{2}} {tanh ( \frac{e {ψ}_{0} z}{4 {k}_{b} T} )}^{2} {e}^{- a κ}$$

where nᵢ=Cᵢe²10³N_{A}z², Cᵢ is the electrolyte concentration (M), N_{A} is Avogadro's number, z is the electrolyte valence, e is the elementary charge, Ψ_{O} is the potential at the surface of the NC, k_{B} is Boltzmann's constant, T is temperature, and κ⁻¹ is the Debye length, defined as:

$${κ}^{- 1} = \sqrt{\frac{{ɛɛ}_{0} {k}_{B} T}{2 {e}^{2} {z}^{1} {n}_{t}}}$$

where ε is the relative permittivity of the dispersing medium and ε_{O} is the permittivity of free space. An immediate observation one can make is that the electrostatic repulsion decreases as a function of particle diameter. Secondly, the Debye length, and thus the electrical double layer, collapses with increasing valence and concentration of the electrolyte. The assertion that an electrical double layer plays a significant role is unlikely. In FIG. 3a, conservative estimates for conditions during a phase transfer of 8 nm NCs from a nonpolar solvent to water containing a 1:1 (z=1) 0.01 M electrolyte (ionic ligands) were used. 0.1 M solutions have been reported on multiple occasions (Sugimoto et al., The Journal of Physical Chemistry C, 117(13):6807-6813, 2013; and Kovalenko et al., Journal of the American Chemical Society, 132(29):10085-10092, July 2010). No assumptions were made about the composition of the NCs by treating the Hamaker constant as an independent variable spanning nearly four orders magnitude. The gray area represents the experimental values (Dong et al., Journal of the American Chemical Society, 133(4):998-1006, 2010) and calculated values (Israelachvili, Intermolecular and surface forces: revised third edition. Academic press, 2011) containing many metals (Ag, Au, and cu), SiC, and sulfides (CdS, PbS, and ZnS). The area is bounded by A₂₁₂=3.0×10⁻²⁰ J (CdS) and A₂₁₂=40.0×10⁻²⁰ J (Au). Experimental agreement with calculated values using Lifshitz theory is typically within 20% error (Dong et al., Journal of the American Chemical Society, 133(4):998-1006, 2010; and Israelachvili, Intermolecular and surface forces: revised third edition. Academic press, 2011).

For the scenario presented in FIG. 3a, none of the DLVO curves predict a significant energy barrier (Φ_{B} greater than a few k_{T}) needed to achieve a stable colloid with an electrical double layer. Under appropriate conditions, it is conceivable that an electrical double layer could stabilize an 8 nm CdS NC water (A₂₁₂=3.4×10⁻²⁰ J). A surface charge of ±75 mV would be needed to establish a approximately 10k_{B}T barrier. However, in FIG. 5b, for the case of Au, which has a much higher Hamaker constant of A₂₁₂=40.0×10⁻²⁰ J. Colloidal Au nanocrystals have been reported as stable in polar solvents following solution exchange with a variety of “ionic ligands” (Sugimoto et al., The Journal of Physical Chemistry C, 117(13):6807-6813, 2013; Bergström, Advances in colloid and interface science, 70:125-169, 1997; and Kovalenko et al., Science, 324(5933):1417-1420, June 2009). In FIG. 5b, the surface charge needed to stabilize Au in water with an electrical double layer alone was investigated. Unreasonable surface potentials of 200-300 mV would be needed to establish even a modest barrier to agglomeration.

An electrical double layer alone is likely not the source of colloidal stability observed after “ionic ligand” exchange. Returning to the Si NC system, in contrast to solution-synthesized NCs, gas-phase synthesis from hydride precursors yields NCs that are uniquely free of organics. Thus, there is an opportunity to analyze the mechanism of colloidal stability in an environment unhampered by previous solution-phase chemistries. Also, one can assuredly start with a “bare” or ligand-less NC surface, which is the most likely scenario to occur after treating the NC surface with “ionic ligands.” Take for example, a calculation by Talapin et al. (Fafarman et al., Journal of the American Chemical Society, 133(39):15753-15761, October 2011) where a conservative estimate of 9 to 11 elemental charges are at the surface of a 4.2 nm NC with sulfide ligands. This corresponds to just 4 or 5 sulfide ligands. If the diameter of a sulfide ion is estimated to be 2 times the length of a disulfide bond (0.205 nm), then approximately 95% of the NC surface is unaccounted for. This is derived from the potential at the slipping plane (ζ-potential), which is 1 to 2 solvent diameters away from the surface at 0.01 M and would only lead to an underestimate of Ψ₀ of approximately 17% (Nag et al., Journal of the American Chemical Society, 134(33):13604-13615, August 2012). Still, even if the estimate is off by an order of magnitude, then approximately 52% of the NC surface is still unaccounted for.

In light of this, what is mostly interacting with the NC surface can be examined, i.e., the solvent. Reports on solvent-dependant stability already raise questions. For instance, in conventional DLVO theory, the solvent is represented as a continuous medium characterized by one parameter, ε. Indeed, ε is often sited as the determining factor for a suitable solvent for redispersion after ionic ligand treatment. However, in these same instances, acetonitrile (ε=36) is often used as an “anti solvent” to crash out NCs, whereas n-methyl-pyrrolidone (ε=32.6) is often used as a dispersing solvent. Clearly, taking only into account the dielectric properties of the dispersing medium is not enough.

What is often referred as an “extension” to classical DLVO can be examined by taking into account the collective effect of molecular interactions at and near a colloidal particle surface (Dong et al., Journal of the American Chemical Society, 133(4):998-1006, 2010; and Nag et al., Journal of the American Chemical Society, 134(33):13604-13615, August 2012). It is often referred to as the “solvation” potential. It is well known to exist experimentally shown to be an exponential function from the surface. Applying the Derguin approximation for a spherical particle yields:

φₛ=2παλΔG_{AB}e^{d}^{₀}^{-α/λ}

where λ is the is the solvent correlation length, which has been shown to be between 0.6 nm and 1.1 nm for water (Carel J Van Oss. Interfacial forces in aqueous media. CRC press, 2006; and Churaev et al., Journal of colloid and interface science, 103(2):542-553, 1985), d₀ is the minimum separation due to Born repulsion (=0.158 nm), and ΔG_{AB} is interpreted as the acid-base free energy per unit area (mJ m⁻²).

FIGS. 3a and b add this potential to classical DLVO theory and apply it to the Si NC system under the conditions measured in FIG. 2a 0.01M electrolyte concentration. ΔG_{AB} can be taken as the free parameter. The Hamaker constant of Si across DMSO is even greater than that of Au across water (6.3×10²⁰ J). Still, if a solvent correlation length of two DMSO diameters (approximately 0.76 nm) is assumed, then a ΔG_{AB} of 40 mJ m⁻² is needed to obtain a barrier of approximately 20 kT . This is consistent with the values found in the literature (Dong et al., Journal of the American Chemical Society, 133(4):998-1006, 2010).

The solvation potential, Φ_{S}, can be positive (repulsive) or negative (attractive). A repulsive potential occurs when the the surface of the particle is said to be “hydrophilic.” For this discussion, it more suitable to consider the surface Lewis acidic. Conversely, an attractive potential occurs when the surface is “hydrophobic,” which means the molecules interact more favorably with themselves than with the surface. Thus, in strong hydrogen-bonding solvents such as water or formamide, an attractive component always exists. Thus, it is proposed that the pre-exponential Gibb's free energy factor into the sum of the free energies of competing molecular interactions at the NC surface (ΔG_{NC-m}) and between molecules (ΔGₘ₋ₘ):

ΔG_{AB}=ΔG_{NC-m}−ΔGₘ₋ₘ

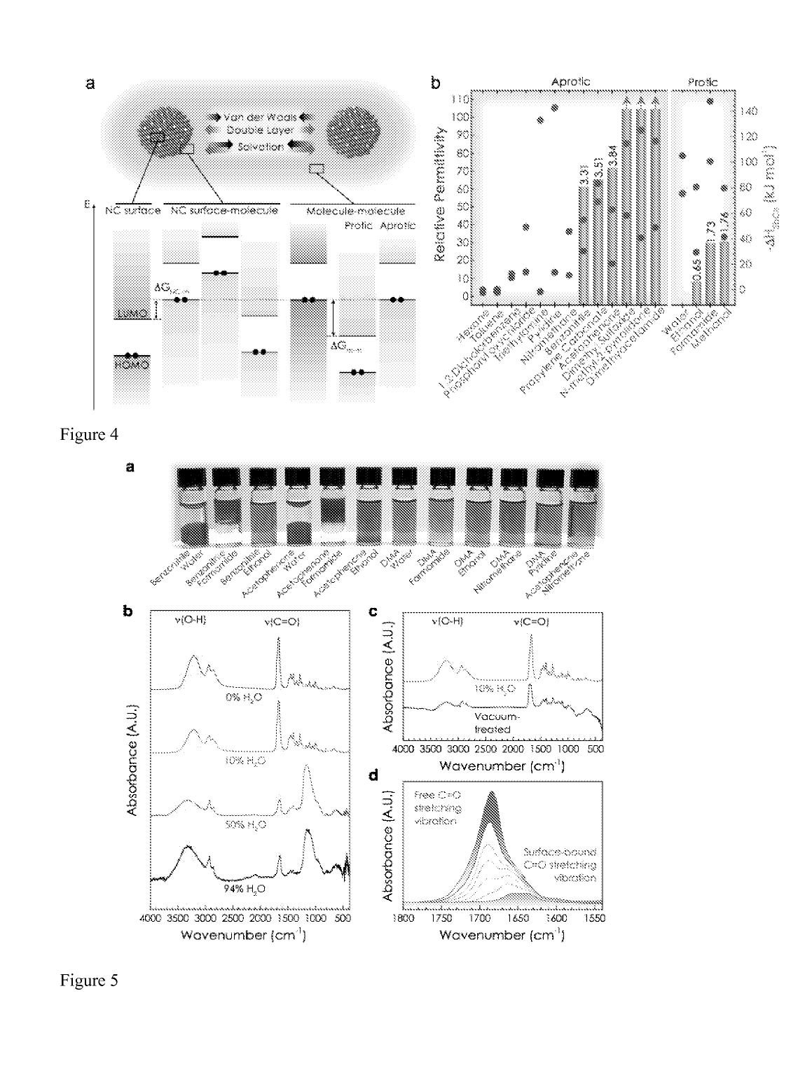

From this expression, ΔGₘ₋ₘ goes to zero for aprotic (non-hydrogen bonding) solvents. A schematic diagram of this provided in FIG. 4a, which considers a simple molecular orbital picture of acid base interactions at the NC surface and in the bulk solvent. First the LUMO of the NC surface must be low enough (acidic) to interact with Lewis basic groups of ligands or solvent. In the presently disclosed system, this was achieved with the B(III) surface chemistry, but all metal-based NCs should have Lewis acidic metal surface atoms. If the LUMO of the NC surface is taken as reference, the first criterion for a net repulsive solvation force is ΔG_{NC-m} must be greater than, or within a few k_{B}T of, zero in order to have a favorable interaction. Secondly, ΔGₘ₋ₘ must be smaller than ΔG_{NC-m}.

The consequences of these interactions are clearly observed in FIG. 4b, which plots the highest achievable Si NC concentration (gray bars) as a function relative permitivity and the basicity (negative enthalpy of complexation of the solvent with the reference acid SbCl₅). For aprotic solvents, intermolecular interactions are negligible compared to their basicity and ΔGₘ₋ₘ goes to zero. Thus the trend is simple. Solvents with, at least, a modest relative permittivity and high basicity provide good stability to the Si NCs. For aprotic solvents, the story is also consistent with the relative strengths of ΔGₘ₋ₘ and ΔG_{NC-m}. Water has a large basicity but is well known for its ability to self-associate via hydrogen bonds, so no stability is provided. Formamide has similar H-bonding properties but a higher basicity, so limited stability is achieved. Methanol and ethanol both have modest basicity and H-bonding properties and thus provide limited stability as well.

Unfortunately, the ability of this model to predict stability is limited without readily available thermodynamic data. Still, it can qualitatively explain what classic DLVO theory could not. FIG. 5a does this claim justice. By simply looking at the relative strengths of ΔGₘ₋ₘ and ΔG_{NC-m}, one can choose combinations of solvents to form stable solutions that are not possible in a single solvent system. For instance, adding water or formamide to a stable solution of Si NCs in a solvent of mediocre basicity, such as benzonitrile or acetophenone, will flocculate the colloid. The strong inter-hydrogen bonding of the water molecules decreases ΔG_{AB}. However, after addition of a water or form amide to a strongly basic solvent, such as dimethylacetamide, stability is maintained and solutions of Si NCs in water is now possible. In effect, ΔG_{AB} was lowered but not enough to flocculate the Si NCs. Moreover, after first dispersing in dimethylacetamide stability in solvents that do not provide stability on their own, such as nitromethane or pyridine, is now possible. All of these observations are made by only considering molecular interactions, not long range forces such as the electrical double layer championed by classical DLVO theory.

The FTIR spectra of FIG. 5b illustrate a particularly attractive co-solvent system of NMP and water. Water-stable NCs are desirable for many reasons such as biocompatibility and cost efficiency. Si NC stability in solutions of 94% water can be demonstrated by simply first forming a highly concentrated solution in NMP, then diluting with water. Interestingly, even at 10% water by volume, the surface of the Si NCs remain unoxidized, which can be observed by a lack of Si—O—Si vibration at 1090 cm⁻¹. Si NCs are extremely reactive in ambient air atmosphere. However, these solutions were stored in ambient condition for weeks before FTIR was measured. Moreover, simply pulling modest vacuum (approximately 10⁻³ mbar) will remove adsorbed water from the surface of the NC (FIG. 5c). It appears the NMP molecules bound to the surface through an acid-base complex actually protect the Si NC from oxidation. Still, the NMP molecule can also be removed with vacuum as seen in FIG. 5d, which takes spectra as function of pumping time. The vC═O characteristically redshifts as a NC films evaporates and only the molecules at the NC surface remain.

This work was begun by demonstrating a versatile Lewis acidic B(III) surface and demonstrated colloidal stability with a typical ligand-binding scheme for stability in non polar solvents. The Si NCs were then used as a model system to explore stability in polar solvents, which pointed out the inadequacies of current beliefs within the NC community regarding the mechanism of colloidal stability due to “ionic ligand” treatment of NCs. Given the great breadth of NC materials explored using “ionic ligands”, it is difficult to claim generality to observations. Still, it was demonstrated that achieving colloidal stability in NC systems using an electrical double layer alone is exceedingly difficult. Thus a model that accommodates specific molecular interactions at the NC surface and within the bulk solvent can be adopted. The model nicely predicts the ability particular solvents, and perhaps more importantly, mixtures of solvents, which enabled stable Si NC colloids in a versatile array of media.

### Experimental

Si NC synthesis: Doped silicon nanoparticles were formed in a continuous-flow low-pressure plasma reactor from an argon-silane-diborane gas mixture. The reactor consisted of a borosilicate glass tube through which the reactant gases were flowed. Typical flow rates were 30-50 standard cubic centimeters per minute (sccm) of argon, 0.4-0.6 sccm of silane, 0-2 sccm of diborane diluted in hydrogen (10%). Radio frequency (rf) power at 110-130 W and 13.56 MHz was supplied to ring electrodes to form crystalline nanoparticles in the plasma.

Si NC colloid formation: Powder samples of boron-doped and codoped silicon nanocrystals were collected directly from the gas-phase by impacting them onto a substrate mounted onto a manual feed-through located inside the reactor. A rectangular nozzle was placed in between the deposition and plasma region to accelerate the particles and impact them directly onto the substrate. The substrate was then retracted into a portable loadlock and transferred air-free to a N₂-purged glovebox for further characterization and processing. Besides accelerating the silicon nanocrystals, the rectangular nozzle controlled the gas pressure in the plasma region by restricting the flow. Adjusting the width of the nozzle opening allowed for the pressure to change independently of the gas flow. This method was used to produce nanocrystals at reactor pressures ranging from 90 to 150 Pa. As a result, the nanoparticle size could be precisely controlled between 5 and 15 nm.

XPS: XPS samples were prepared by directly impacting a <50 nm thin film of Si NCs onto a Au-coated Si wafer. Colloidal Si NC sample were prepared by drop-casting a dilute solution onto a Au-coated Si wafer. XPS spectra of the B1s were taken by integrating scans for approximately 2 hours. The N1s was integrated for up to approximately 30 minutes. Peaks were assigned by using the C1s peak as a reference at 285 eV.

Solvents: The following solvents were purchased from Sigma Aldrich (purity and grade are included if available): Hexane (≧97.0%, HPLC), Toluene (99.9%, HPLC), 1,2-dichlorobenzene (99.9%, HPLC), Phos-phoryl oxychloride (99.9%, HPLC), triethylamine (99.9%, HPLC), Pyradine (99.9%, HPLC), Nitromethane (99.9%, HPLC), benzonitrile (99.9%, HPLC), propylene carbonate (99.9%, HPLC), acetophenone (≧99.0%, GC), Dimethyl sulfide (99.9%, HPLC), 1-methyl-2-pyrrolidone (≧99%, HPLC), Dimethylacedamide (≧99%, HPLC), Ethanol (≧99%, HPLC), Formamide (≧99%, HPLC), Methanol (≧99%, HPLC). Solvents were stored on a Shlenk line over 3-angstrom molecular sieves for at least 24 hours after three freeze-pump-thaw cycles were performed to remove residual water and oxygen prior to use.

DLS and ζ-potential: DLS spectra and electrophoretic mobility were evaluated on a Brookhaven ZetaPALS instrument using phase-angle light scattering with varied conditions between 2 V and 200 V at frequencies between 2 and 5 Hz depending on the stability response of the colloids. ζ-potential values were evaluated from the electrophoretic mobility by applying Henrys equation. Relative permittivities were obtained from the Landolt-Börnstein Database (Landolt-Bornstein. Static Dielectric Constants of Pure Liquids and Binary Liquid Mixtures. SpringerMaterials-The Landolt-Bornstein Database, 2008).

Colloid Concentration: UV-Vis absorption of centrifuged Si NC solutions was performed on a Cary 5E UV-Vis spectrophotometer. Centrifugation was done at 4000 rpm for up to 30 minutes. After centrifugation, optically transparent solutions indicated insignificant scattering, and the Beer-Lambert law (A=εlc) was employed to determine mass concentration from absorption by integrating the absorption spectra between 550 nm to 800 nm. The absorbance, A, is linearly dependent on concentration, c. The path length through the solution, l, and the extinction coefficient, ε, are constants. A was determined by integrating under the absorbance curve. The absorbance of 5 mg of Si NCs in 3 ml of DMSO, A_{b}, did not change after centrifugation, so the concentration, c_{b}, was known. It was used to determine the unknown concentration, cₒ, of other solutions relative to Si NCs in DMSO. After subtracting the background solvent, the concentration of other solutions was obtained from: Aₒ/A_{b}=cₒ/c_{b}.

ATR-FTIR: ATR-FTIR experiments were done on a diamond ATR crystal using a Bruker Alpha FTIR spectrometer inside a N₂-atmosphere glovebox. Spectra were typically collected by averaging 20 scans at 2 cm⁻¹ resolution.

### Example 2

Si NCs and Si NC inks were prepared as previously described and spray coated onto substrates for characterization and testing.

The spray coating system was placed in a small glovebox to eliminate exposure to solvents. The airbrush was connected directly to a nitrogen tank and pressures were varied using a gas regulator. The airbrush was positioned horizontally, and directed at a vertically placed hot plate, onto which the substrate was taped. Variables studied in this work included the distance between the airbrush and the substrate, nitrogen pressure, hot plate temperature, Si NC colloid flow rate, and solvents.

The distance between the airbrush and the substrate is defined as the distance between the tip of the airbrush to the substrate surface. The range of distances tested was 1 to 25 centimeters.

Nitrogen pressure refers to the nitrogen pressure that flows through the airbrush allowing the colloid to be atomized and forced out of the airbrush. The pressure range for this experiment was set at 15-50 psi using a gas regulator.

The substrate was placed directly onto a hot plate, and the hot plate temperature was used to control the temperature of the substrate, which in turn controlled the evaporation rate of the solvent. The temperature ranged from room temperature up to 200° C. depending on the solvent used for the ink. The substrate was allowed to warm up for 15 minutes for the temperature to reach equilibrium.

The Si NC ink flow rate was defined as the amount of ink in microliters exiting the airbrush per second. The flow rate ranged from 3 to 170 μL/second. The flow rate of 170 μL/second was the maximum flow rate for the airbrush.

The two different solvents used were methanol and dimethyl sulfoxide (DMSO), solvents which were chosen for their ability to disperse the silicon nanoparticles and create a clear and stable colloid. A nanoparticle concentration of 3 mg/ml was used.

Before each spray coating experiment, the silicon substrates were cleaned using a heated piranha solution for 15 minutes, rinsed with deionized water, and then placed in a UV Ozone chamber for 30 minutes. Polyimide substrates (available under the trade designation KAPTON from DuPont) were also used but could not be cleaned using the piranha solution. Instead the KAPTON substrates were cleaned with acetone and isopropanol and then rinsed with deionized water, followed by a 30 minute UV ozone exposure.

Additional exemplary embodiments of the present disclosure are illustrated by the following figures.

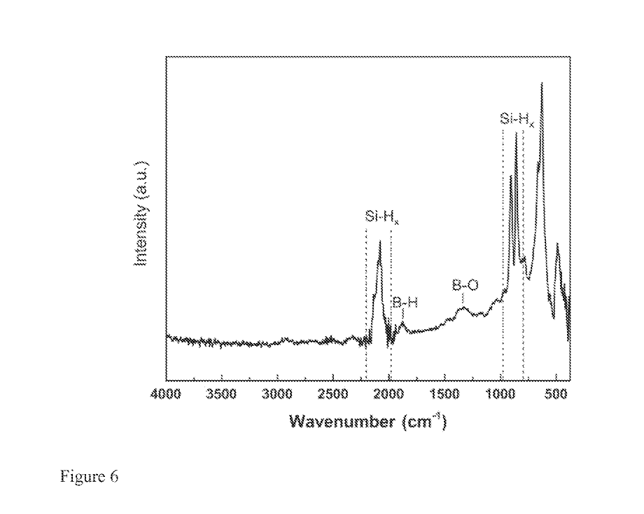

FIG. 6 illustrates an exemplary IR Spectrum of 10%-boron doped nanoparticles. The lack of a silicon-oxide feature indicates an oxide free surface.

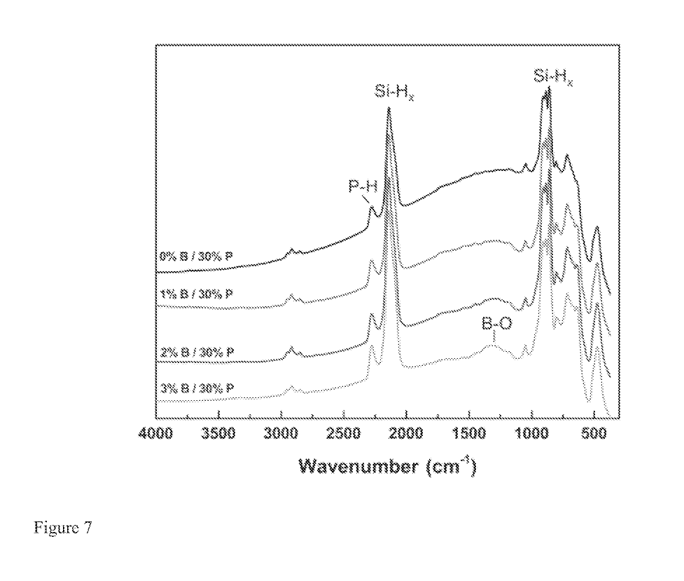

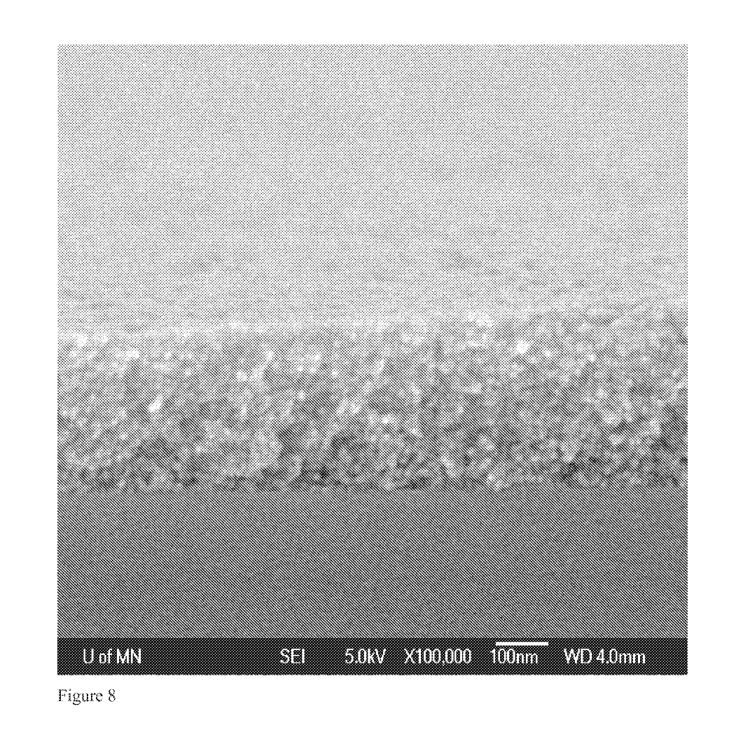

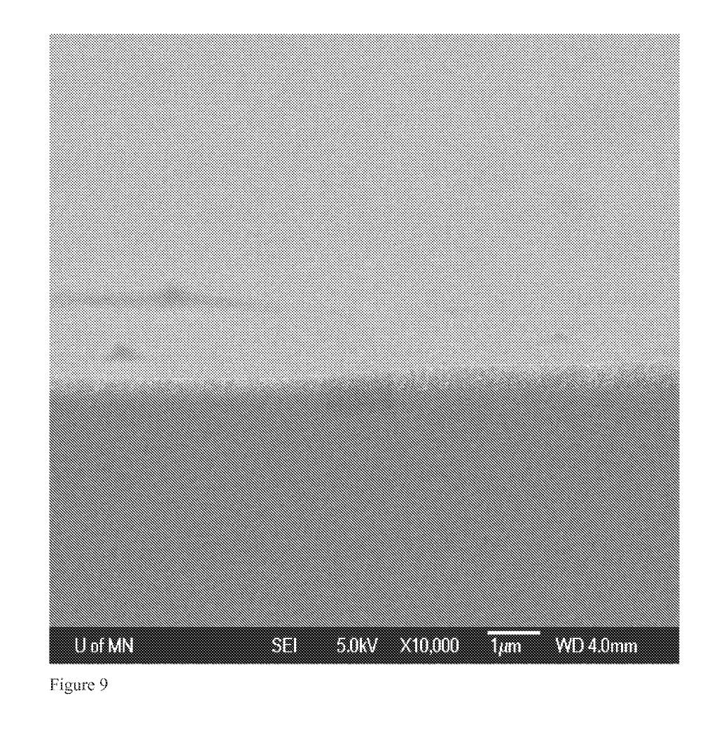

FIG. 7 illustrates an exemplary FTIR Spectrum of phosphorus doped and codoped nanoparticles. These particles exhibit plasmonic features.

FIG. 8 illustrates an exemplary SEM cross-section image of a spray coated film of boron-doped nanoparticles.

FIG. 9 illustrates an exemplary SEM cross-section image of a spray coated film of boron-doped nanoparticles showing a uniform film with no cracks.

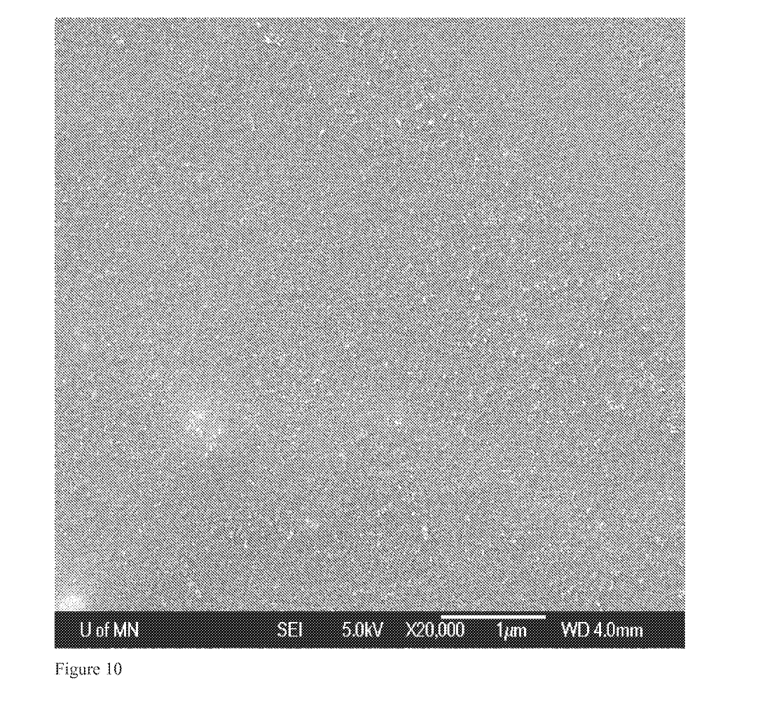

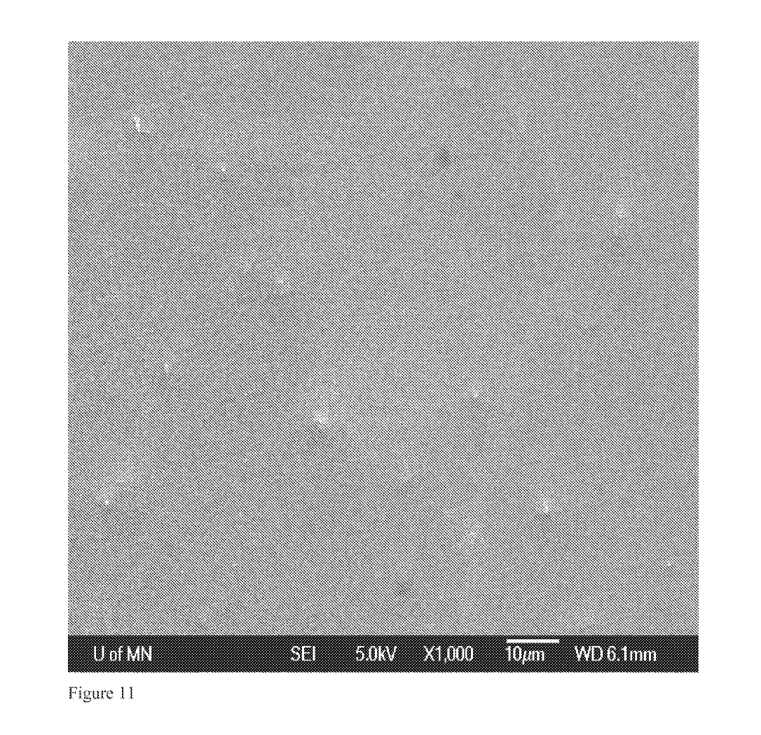

FIG. 10 illustrates an exemplary SEM top-view image of a spray coated film of boron-doped nanoparticles on flexible polyimide substrates (available under the trade designation KAPTON from DuPont) showing a uniform film with no cracks.

FIG. 11 illustrates an exemplary SEM top-view image of a spray coated film of boron-doped nanoparticles on flexible polyimide substrates (available under the trade designation KAPTON from DuPont) showing a uniform film with no cracks.

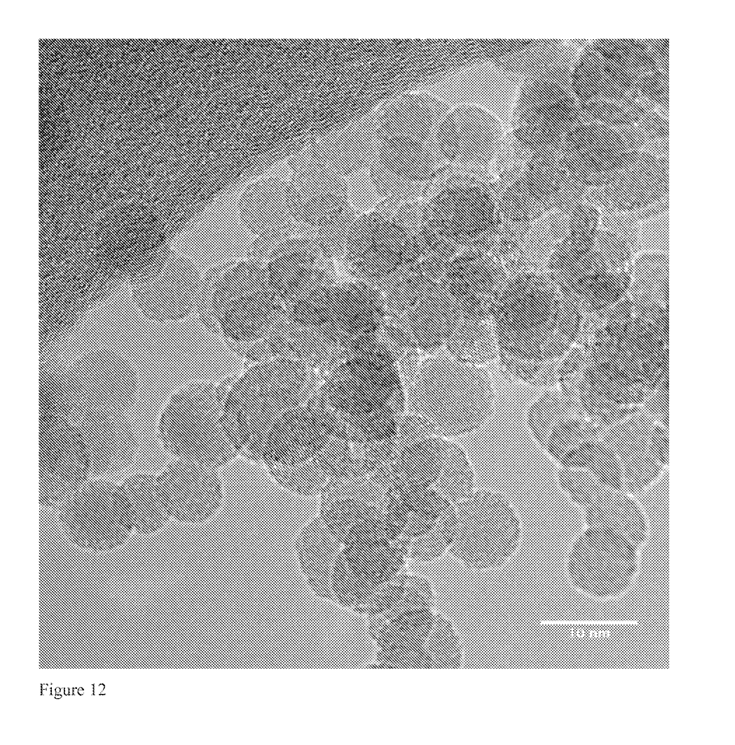

FIG. 12 illustrates an exemplary TEM image of 8 nm crystalline boron-doped nanocrystals showing a monodisperse size distribution. There is no significant oxide shell visible.

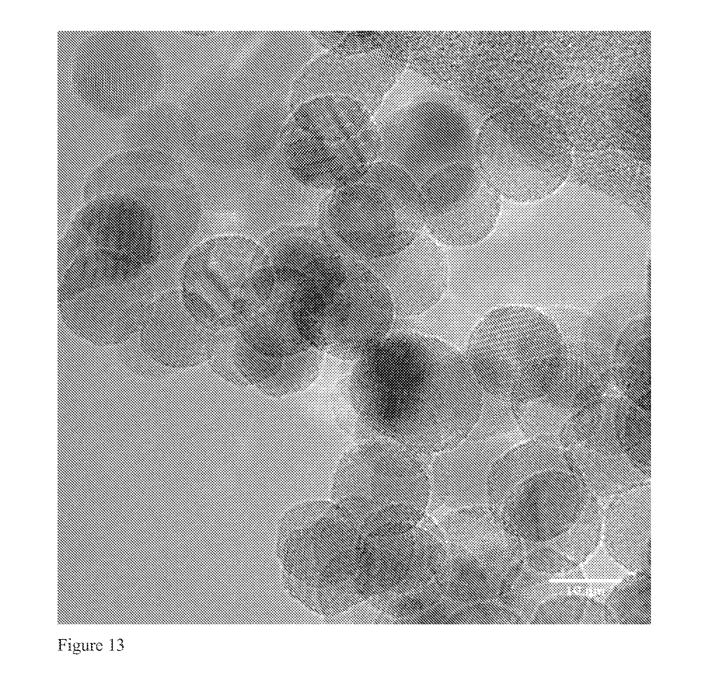

FIG. 13 illustrates an exemplary TEM image of 12 nm crystalline boron-doped nanocrystals showing a monodisperse size distribution. There is no significant oxide shell visible.

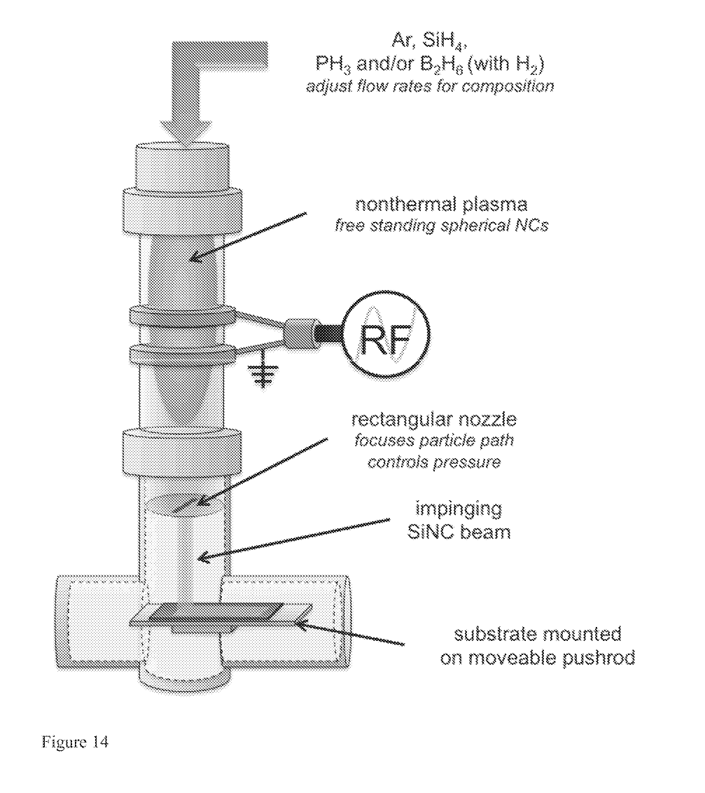

FIG. 14 illustrates an exemplary schematic of the plasma reactor which is used to produce boron or codoped nanocrystals.

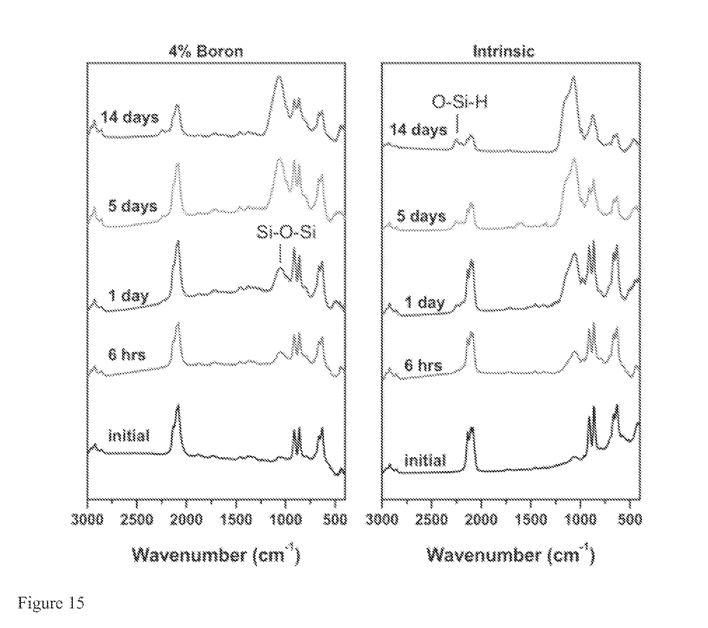

FIG. 15 illustrates an exemplary FTIR spectra comparing the oxidation rate of boron-doped and undoped nanocrystals. The boron-doped nanocrystals oxidize significantly slower as is determined by the silicon-oxide feature in the spectra.

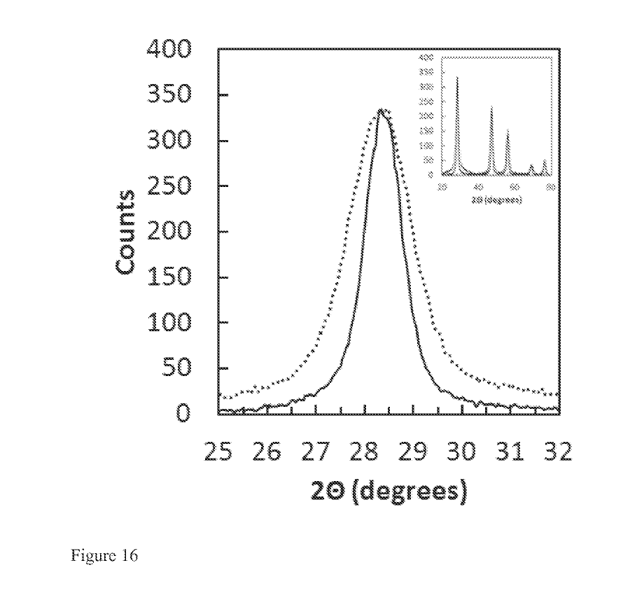

FIG. 16 illustrates an exemplary XRD Spectra of boron-doped nanocrystals with two sizes (8 nm and 12 nm). The spectra show fully crystalline samples.

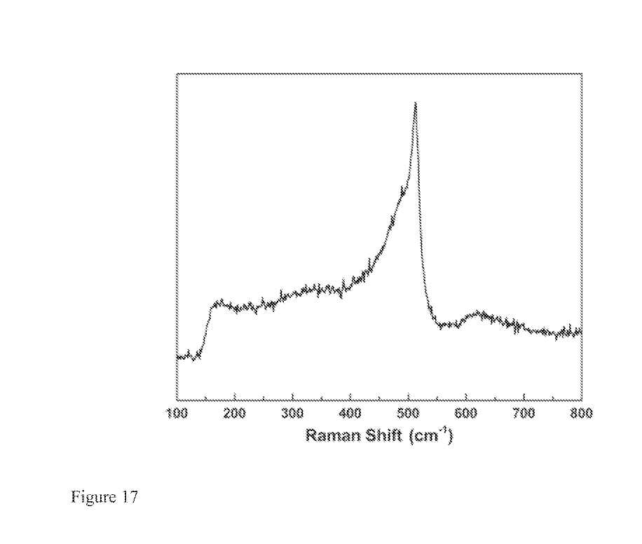

FIG. 17 illustrates an exemplary Raman spectrum of a boron-doped nanocrystal. The spectrum shows a fully crystalline sample.

### Example 3

### Ge and SiGe NC Synthesis and Deposition

A low pressure nonthermal plasma was used to synthesize B- and P-doped SiGe NCs. For synthesis borosilicate glass tubes with diameters ranging from 0.25 to 1 inch were used. SiH₄ (100%) and GeH₄ (diluted 10% in Ar) were used as the precursor gases. PH₃ (15% diluted in H₂) or B₂H₆ (10% diluted in H₂) were added to the SiH₄:GeH₄:Ar mixture to dope the SiGe NCs. The gas pressure during synthesis was typically held between 150 and 250 Pa. A radio frequency power of 80-130 W was applied to two electrodes. Argon flow rates were 30-60 sccm, SiH₄ flow rates were 0-1 sccm, GeH₄/Ar flow rates were 0-10 sccm, PH₃/H₂ flow rates were 0-5 sccm, and B₂H₆/H₂ flow rates were 0-5 sccm.

Particle collection was achieved by placing a substrate (SiO₂ or Si wafer) in the particle beam formed by a rectangular nozzle in the gas flow. The nozzle used to impact films was a beveled orifice, with adjustable height, and 12 mm width. For depositing SiGe NCs the nozzle was set to a width of 0.61 mm.

NC Inks were formed by directly adding a solvent to the NCs. Similar solvents as the ones used for Si can be used for Ge and SiGe as well.

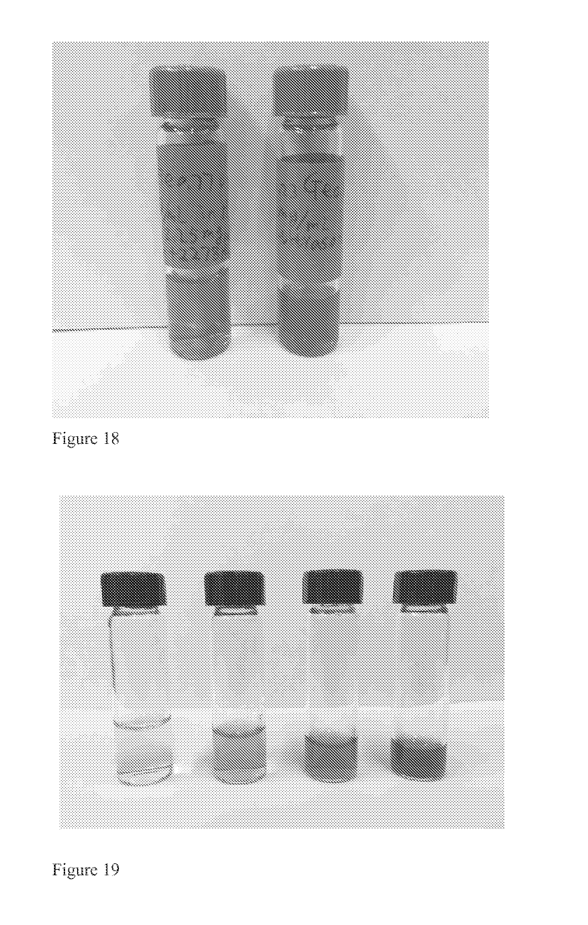

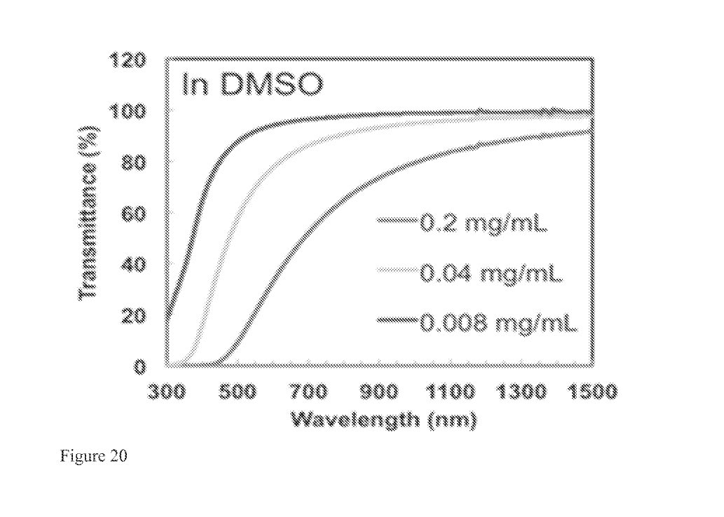

Compared to pure silicon NCs, we see similar behavior for germanium NCs and SiGe alloy NCs. FIG. 18 illustrates an exemplary image that shows two samples of Ge NCs and SiGe NCs in dimethyl sulfoxide solvent. FIG. 19 illustrates exemplary images that show four samples of SiGe NC inks with different concentrations in dimethylsulfoxide (DMF). FIG. 20 illustrates an exemplary transmission spectrum for SiGe NCs in solution.

### Example 4

Nanocrystals (NCs) that exhibit a localized surface plasmon resonance (LSPR) are a versatile class of nanomaterials that are finding application in numerous fields such as light concentrators in solar cells (Kelzenberget al., Nature Materials 2010, 9:239-244), bioimaging (Dreaden et al., Chemical Society Reviews 2012, 41:2740-2779), and nanoelectronics (Ozbay, Science 2006, 311:189-193). A broad variety of materials have been proposed for plasmonic applications, spanning a wide range of wavelengths (Liu et al., Chemical Society Reviews 2014, 43:3908-3920). In recent years degenerately-doped semiconductor NCs have attracted significant attention. In contrast to noble metal NCs (Vollmer and Kreibig, Optical Properties of Metal Clusters, Springer Ser. Mat. Sci, 1995), in which the carrier density is fixed, the position of the LSPR of semiconductor NCs can be tuned by adjusting the free carrier concentration of the NCs (Luther et al., Nature Materials 2011, 10:361-366).

Several strategies have been applied to control the free carrier concentration and the resulting LSPR of semiconductor NCs. The most common strategies are the introduction of n-type or p-type dopants (Kanehara et al., Journal of the American Chemical Society 2009, 131:17736-17737; Rowe et al., Nano Letters 2013, 13:1317-1322; Zhou et al., ACS Nano 2015, 9:378-386; and Buonsanti et al., Nano Letters 2011, 11:4706-4710), tuning of the NC composition (Dorfs et al., Journal of the American Chemical Society 2011, 133:11175-11180; and Liu et al., Chemistry of Materials 2013, 25:4828-4834), or interactions between the NC surface and a solvent (Wheeler et al., Nature Communications 2013, 4). This allows for the control of the LSPR wavelength while the NC size or shape remain unaffected. A major disadvantage of using semiconductor NCs for plasmonics is their lack of air-stability and the need for precise doping and stoichiometry control. Metal chalcogenides nanocrystals such as copper sulfide, for example, become degenerately doped during oxidation, and as a result the plasmon resonance will blue-shift (Kriegel et al., J. Journal of the American Chemical Society 2012, 134:1583-1590).

Recently it was shown that a localized surface plasmon resonance emerges for highly phosphorus-doped and boron-doped silicon nanocrystals (Si NCs) (Rowe et al., Nano Letters 2013, 13:1317-1322; and Zhou et al., ACS Nano 2015, 9:378-386). Control of the plasmonic properties of Si NCs is highly desired for integration with electronics. While gas-phase plasma synthesis methods allow for excellent doping control of both n-type and p-type dopants in Si NCs (Gresback et al., ACS Nano 2014, 8:5650-5656; and Zhou et al., Applied Physics Letters 2014, 105:183110), a deeper understanding of the dopant dynamics is necessary to control the plasmonic behavior of these NCs.

Here we demonstrate the plasmonic behavior of as-produced and post-synthesis treated phosphorus-doped and boron-doped Si NCs, and report for the first time air-stable silicon-based plasmonic nanomaterials. While the synthesis method of phosphorus-doped and boron-doped Si NCs is identical, the plasmonic behavior of boron-doped Si NCs varies greatly compared to phosphorus-doped Si NCs. We investigate the effect of post-synthesis treatments such as annealing and oxidation on the plasmonic properties of the NCs. This allows us to propose a new model which describes the dopant location and dynamics during synthesis and after post-synthesis treatments for both phosphorus-doped and boron-doped Si NCs. As a result we are able to produce air-stable plasmonic NCs with control of their plasmonic properties, opening the door to novel Si-based plasmonic devices.

Freestanding boron and phosphorus-doped Si NCs, with an average size of 8 nm, are produced using a nonthermal plasma process which has been described previously (Rowe et al., Nano Letters 2013, 13:1317-1322; Gresback et al., ACS Nano 2014, 8:5650-5656; and Mangolini et al., Nano Letters 2005, 5:655-659). The indicated fractional dopant flow rates are defined as X_{PH}_{₃}=[PH₃]/([SiH₄]+[PH₃])×100% and X_{B}_{₂}_{H}_{₆}=2[B₂H₆]/([SiH₄]+2[B₂H₆])×100%, where [PH₃], [SiH₄] and [B₂H₆] are the gaseous precursor flow rates of phosphine, silane and diborane, respectively. The Si NCs are deposited directly onto a glass substrate, silicon wafer or an aluminum-coated silicon wafer for further analysis. Fourier Transform Infrared Spectroscopy (FTIR) measurements of as-produced NCs are performed in a nitrogen-purged glovebox environment.

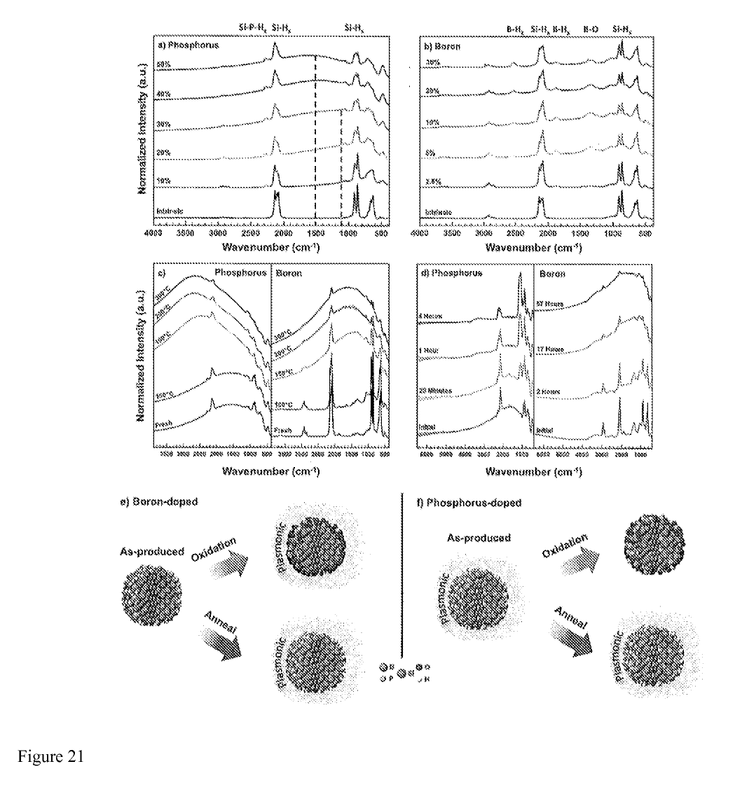

FIGS. 21a and 21b show the FTIR spectra of as-produced phosphorus-doped and boron-doped Si NCs with increasing fractional dopant flow rates. These results show a significant difference in plasmonic behavior between the two dopants. For sufficiently high doping concentrations, a plasmon resonance emerges for phosphorus-doped Si NCs. The plasmon peak position blue shifts for increasing fractional dopant flow rates as a result of the higher doping concentration. The free carrier concentration is calculated by measuring the peak position of the plasmon resonance (Luther et al., Nature Materials 2011, 10:361-366). For a fractional dopant flow rate of 30% we find a free carrier concentration of 1:9×10²⁰ cm⁻³. Using a nanoparticle size of 8 nm we estimate that highly phosphorus-doped Si NCs contain approximately 100 active phosphorus dopants per NC. In addition, there is a phosphorus-hydride stretch visible at 2276 cm⁻¹ that becomes more pronounced for higher doping concentrations. This suggests that the surface of the NC also contains a significant amount of phosphorus which is likely inactive (Chen et al., The Journal of Physical Chemistry C 2010, 114:8774-8781).

In contrast to phosphorus-doped Si NCs, the as-produced boron-doped Si NCs show no plasmon resonance, even at high fractional dopants flow rates. The boron-hydride and boron-oxide stretches at 2200 cm⁻¹ and 1800 cm⁻¹ indicate that boron is placed on the surface of the Si NC during synthesis, but the lack of a plasmon resonance is a result of the significantly smaller free carrier density compared to phosphorus-doped Si NCs. This difference in phosphorus and boron incorporation efficiency has been shown by various computational models (Ma et al. J. Applied Physics Letters 2011, 98:173103; Ma et al., Physical Review B 2013, 87:115318; and Guerra et al., Journal of the American Chemical Society 2014, 136:4404-4409), in which the lower active boron concentration in Si NCs was attributed to the larger formation energy of boron compared to phosphorus in Si NCs. As a result, the boron atoms prefer to reside on or near the surface of the Si NC where it does not affect the free carrier concentration (Pi et al. The Journal of Physical Chemistry C 2011, 115:9838-9843).

Next we discuss the plasmonic resonance behavior after post-synthesis treatments of the Si NCs. The effect of low-temperature annealing in a nitrogen environment on the plasmonic properties of the doped Si NCs is shown in FIG. 21c. Here the FTIR spectra of boron-doped and phosphorus-doped Si NCs are plotted as a function of the annealing temperature. The Si NCs were annealed on a hotplate in an oxygen-free glovebox environment for 10 minutes at each specified temperature. We observe a plasmon resonance for both phosphorus-doped and boron-doped Si NCs as well as a blue shift of the plasmon resonance peak position for increasing temperatures. For phosphorus-doped Si NCs, the blue-shift of the plasmon resonance during annealing corresponds to an increase in free carrier density from 3.45×10²⁰ cm⁻³ to 1.16 10×10²¹ cm⁻³. This shows that an annealing treatment is able to generate additional free carriers for both phosphorus-doped and boron-doped Si NCs. The change in plasmonic behavior could be attributed to an increase in active dopants or a decrease in surface defects.

Differences in dopant behavior are again observed during post-synthesis oxidation of the doped Si NCs in air. FIG. 21d shows the effect of oxidation on phosphorus-doped and boron-doped Si NCs as a function of oxidation time. For the case of phosphorus doped Si NCs, the plasmon resonance disappears as the NCs oxidize. A strong Si—O—Si bridging peak appears at 1050 cm⁻¹ and a back-bonded oxide at 2300 cm⁻¹. This suggests that the oxidation of phosphorus-doped NCs reduces the number of free carriers while an oxide shell forms, as the plasmon resonance disappears after four hours of air exposure.

In contrast, for boron-doped Si NCs, a plasmon resonance emerges and blue shifts as the particles oxidize. This indicates that the oxidation process is able to activate boron dopants. Since the majority of the boron atoms prefer to reside on surface sites, the oxide shell is able to activate these three-fold coordinated surface boron atoms by providing a fourth bond. As a result of this, it is possible to produce air-stable plasmonic Si NCs. This is an important step for the use of these plasmonic NCs in applications.

To describe the difference in dopant dynamics during oxidation we have to look into the Cabrera-Mott oxidation mechanism of the Si NCs (Cabrera et al., Reports on Progress in Physics 1949, 12:163-184). It has been suggested that boron and phosphorus atoms can migrate as a result of the induced electric field during oxidization (Ma et al. J. Applied Physics Letters 2011, 98:173103; and Pi, Journal of Nanomaterials 2012, 2012:1-9). As the induced electric field is pointing toward to surface, boron ions will be pushed into the core while phosphorus is pulled towards the surface. This hypothesis explains the experimentally observed differences in dopant behavior during oxidation.

In addition to the change in plasmonic behavior, we also observe the effect of doping on the oxidation rate of the Si NCs. For phosphorus-doped Si NCs, the oxidation rate is significantly enhanced compared to intrinsic particles, while boron doping strongly reduces the oxide growth, as shown in FIG. 21d. This effect can be explained by considering the enhancement or reduction of the electric field by adding or removing free carriers, as described by the Cabrera-Mott oxidation model. Additional free carriers from activated phosphorus atoms enhances the electric field, and as a result the oxidation rate increases, whereas boron doping decreases the electric field strength.

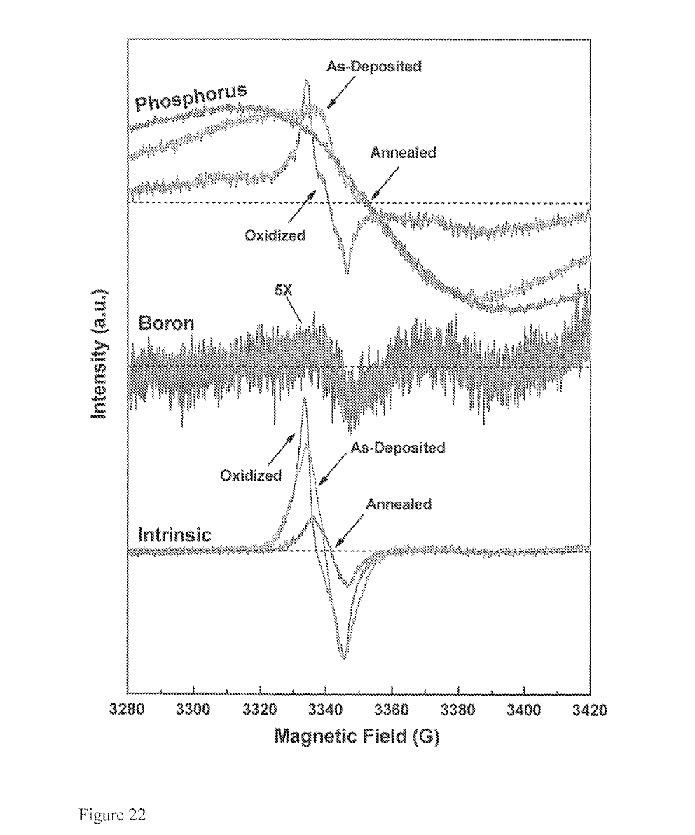

EPR measurements are able to give more insight in the number and type of defects of the Si NCs. FIG. 22 shows the EPR spectra of intrinsic, phosphorus-doped and boron-doped Si NCs. For intrinsic Si NCs we observe the expected reduction in defect density after an annealing treatment. A g-value of 2.0055 originates from silicon dangling bonds on the surface of the NC (D centers). By comparing the integrated area of the peaks we find a decrease of the defect density by approximately a factor of 10, which agrees well with results seen in literature (Niesar et al., Applied Physics Letters 2010, 96:193112-193112-3). After oxidation the line shape and g-value change as expected as a result of the formation of an oxide shell around the nanocrystals (Pb centers), which leads to trivalent silicon atoms at the interface of the silicon core and the oxide (Pereira et al., Physical Review B 2011, 83:155327).

For phosphorus-doped Si NCs a broad spectrum appears with a g-value of 1.998. This is attributed to conduction electrons from active dopant atoms (Zhou et al., Applied Physics Letters 2014, 105:183110; Fujio et al., Applied Physics Letters 2008, 93:021920; Sumida et al., Journal of Applied Physics 2007, 101:033504; and Stegner et al., Physical Review Letters 2008, 100:026803). The g-value of 1.998 has also been previously reported for phosphorus-doped bulk Si (Quirt et al., J. Physical Review B 1972, 5:1716-1728). The as-produced sample contains a feature which is not observed in the annealed spectrum. It is probable this is caused by the reduction in the defect density of the NC surface, leading to the removal of the feature. Low temperature annealing of Si NCs has proven to be capable of reducing the defect concentration by an order of magnitude (Niesar et al., Applied Physics Letters 2010, 96:193112-193112-3). Again, this shows the low temperature anneal reduces the defect density of the NCs, resulting in an increase in free carrier concentration. The ten-fold decrease in defect density agrees well with the increase in free carrier density shown in FIG. 21c.

After oxidation the magnitude of the broad feature reduces significantly and a traditional oxide signal appears. This indicates oxidation is reducing the number of conduction electrons, and an oxide shell is formed. This is consistent with FTIR results, where the plasmon resonance disappears after oxidation.

For the boron-doped Si NCs, very little signal is observed in EPR. The high concentration of boron atoms on the surface of the Si NC leads to a passivation of the surface (Puthen Veettil et al., Applied Physics Letters 2014, 105:222108). Annealing or oxidizing of the Si NCs does not result in any further change of the spectrum. This implies that the boron-doped Si NCs do not form a traditional silicon oxide shell, as there is no signal from Pb-centers present after two weeks of oxidation.

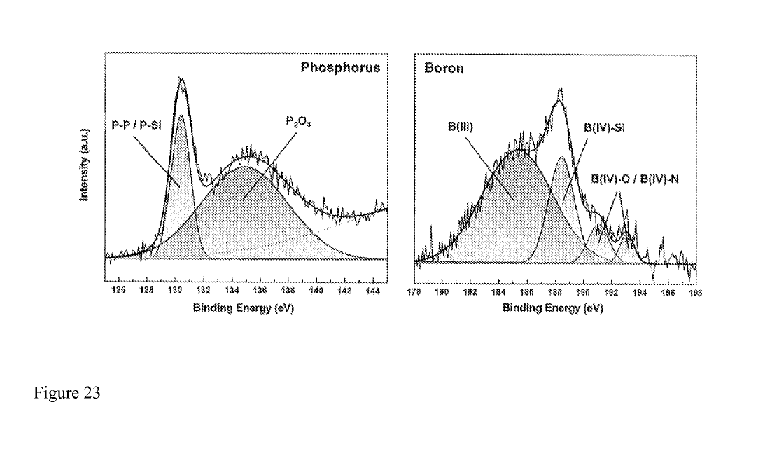

Using X-ray Photoelectron Spectroscopy (XPS) we can further analyze the mechanism of dopant activation. FIG. 23 shows the XPS spectra of phosphorus-doped and boron-doped NCs. For boron (B(1s)) the spectrum can be deconvolved into four peaks (Kazahaya et al., Japanese Journal of Applied Physics Part 2-Letters 1986, 25:L75-L77; Tsutsui et al., Journal of Applied Physics 2008, 104:093709; and Yamauchi et al., Applied Physics Letters 2011, 99:191901). A broad peak at a low binding energy of 185 eV is the contribution from the trivalent state of boron (B(III)). The three remaining peaks correspond to tetravalent boron (B(IV)). The peak at 189 eV results from boron atoms bonded to four silicon or boron atoms. The higher energy peaks are from boron atoms that are attached to an electronegative atom such as oxygen or nitrogen in addition to silicon. The fraction of boron in the tetravalent state will therefore give insight in the number of active boron dopants in the NCs.

The XPS spectra in FIG. 23 indicates a large fraction of trivalent boron is present on the surface of the NC. Based on peak analysis, the fraction of tetravalent boron of as-produced boron-doped Si NCs is 24.7%. After oxidation and annealing this fraction increases to 34.8% and 33.6%, respectively. While it is assumed that not all of the tetravalent boron are active donors, it indicates that an increased number of boron atom becomes activated after these post-synthesis treatments. As such, this supports the development of a plasmon resonance in FTIR during oxidation or annealing.

FIG. 23b shows the XPS spectra for phosphorus-doped Si NCs. The peak located at 135 eV results from phosphorus bonded to oxygen, likely caused by the short air exposure during sample loading. A second peak at a lower binding energy of 130 eV is a result of phosphorus bonded to phosphorus or silicon (Perego et al., Nanotechnology 2009, 21:025602). After oxidation the low energy peak decreases in intensity compared to the higher energy oxide peak. This indicates that a large fraction of phosphorus atoms, previously bonded to phosphorus or silicon atoms, is now bonded to oxygen atoms, and likely become inactive as a result. An annealing treatment shows a slight decrease in the low energy peak intensity. This is confirmed using EDX measurements, which shows a decrease in the phosphorus concentration after the NCs annealing treatment.

Next we analyze the effect of an annealing treatment on oxidized NCs. Previously we showed that annealing is able to generate a plasmon resonance for the case of boron-doped Si NCs, while the plasmon resonance peak of phosphorus-doped Si NCs blue-shifts. The plasmon resonance of oxidized phosphorus-doped NCs returns during the annealing treatment, while oxidized boron-doped Si NCs show a blue-shift. Similar to as-produced Si NCs, annealing is able to generate additional free carriers. This allows for the production of air-stable Si NCs with plasmonic properties.

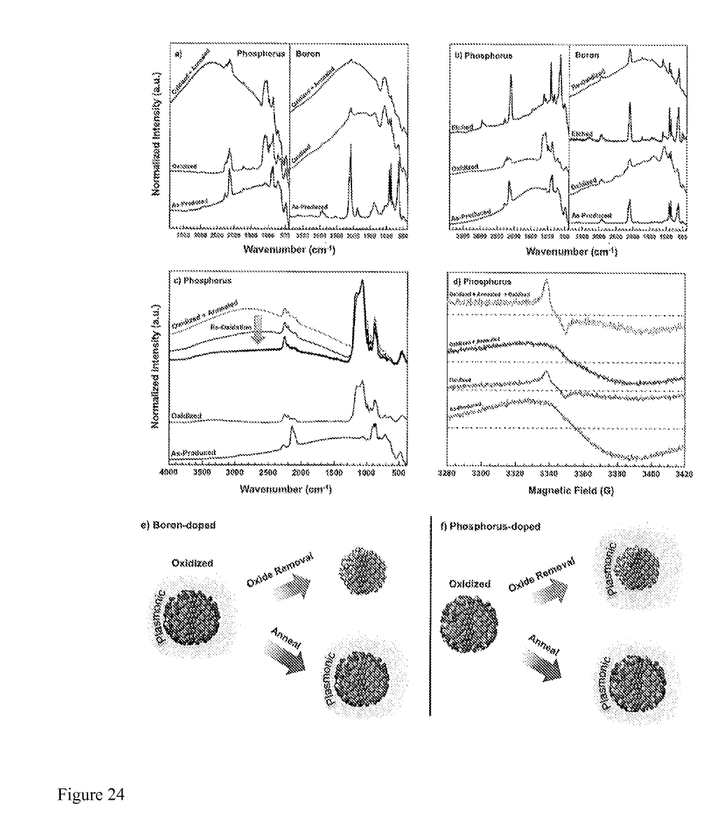

We further investigate the behavior of annealed particles with an oxide shell using FTIR (FIG. 24c) and EPR (FIG. 24d). In FIG. 24c we expose the annealed particles to air for subsequent re-oxidation. After 1 day a plasmon resonance is still visible, albeit reduced in size. The spectra stabilize after 3 days of oxidation. The EPR measurements in FIG. 24d confirm this behavior. After annealing of the oxidized Si NCs a broad signal reappears with a similar g-value as as-produced Si NCs. After the particles re-oxidize for 1 day the broad signal reduces significantly in size and an oxide feature returns. This is in good agreement with the behavior observed in FIG. 24c.

Finally we study the effect of oxide removal and annealing treatments of oxidized Si NCs. Once the doped Si NCs are fully oxidized, we remove the oxide shell using hydrofluoric acid (HF) vapor followed by measurement of the FTIR spectra of the oxide-free Si NCs. The FTIR spectra of the etched Si NCs are shown in FIG. 24b. For phosphorus-doped Si NCs, the plasmon resonance returns after removal of the oxide but is red-shifted with respect to its original position. This shows that phosphorus dopants are removed during etching, which is also confirmed by EDX measurements. The complete removal of the oxide is confirmed by the lack of the two silicon oxide peaks in the FTIR spectrum. Similar behavior was observed by Zhou et al., where a strong plasmonic resonance appeared after removal of the oxide (Zhou et al., ACS Nano 2015, 9:378-386).

For boron-doped Si NCs the plasmon resonance disappears after etching and the spectrum is similar to the spectrum of as-produced NCs. When the boron-doped Si NCs oxidize again, the plasmon resonance returns, confirming the need of an oxide shell for a plasmon resonance to develop. The peak position of the plasmon is not significantly affected by the etching and oxidation step, indicating that the free carrier density remains constant. These observations agree with the proposed model for the dopant behavior during oxidation.

Here we studied the plasmonic properties and dopant dynamics of phosphorus-doped and boron-doped Si NCs. While the synthesis and doping method are identical, phosphorus-doped and boron-doped Si NCs show very different plasmonic behavior. We observed plasmonic resonances for as-produced phosphorus-doped Si NCs with high doping concentrations. As-produced boron-doped Si NCs on the other hand did not have a plasmonic response. This can be mainly contributed to the dopant position and dynamics during NC synthesis. The majority of phosphorus and boron dopants are expected to reside on the surface of the Si NC where they are inactive. Computational results have shown that a larger fraction of phosphorus atoms are incorporated into the Si NC core than boron atoms, which agrees with the observed plasmonic behavior.

After post-synthesis annealing treatments we observe plasmonic behavior for both phosphorus and boron dopants, indicating that annealing is able to generate additional free-carriers for both cases. This is likely a result of NC surface restructuring, as was shown with EPR measurements. Oxidation of the particles again shows opposite dopant behavior, where a plasmon resonance is present in oxidized boron-doped Si NCs while it is not present in oxidized phosphorus-doped Si NCs. This can be reversed by removing the oxide, showing the role of the oxide shell. This also allows us to form air-stable plasmonic nanomaterials using silicon. These results agree well with computational predictions found in literature and give valuable insight on plasmonic and dopant dynamics of Si NCs.

### Experimental

Nanoparticle synthesis: Silicon nanocrystals were synthesized in a continuous-flow, low-pressure plasma reactor from an argon-silane (SiH₄) gas mixture. Dopants were introduced by addition of phosphine (PH₃) or diborane (B₂H₆) to the gas mixture. The reactor consisted of a borosilicate glass tube through which the reactant gases were flown. Typical flow rates were 30-50 standard cubic centimeters per minute (sccm) of argon, 0.4-0.6 sccm of silane, 0-2 sccm of diborane diluted in hydrogen (10%) and 0-2 sccm of phosphine diluted in hydrogen (15%). Radio frequency (rf) power was supplied at 110-130 W and 13.56 MHz to ring electrodes to form crystalline nanoparticles in the plasma. The NCs were collected directly onto glass substrates, silicon wafers, or aluminum-coated silicon wafers and transferred air-free to a nitrogen-purged glovebox using a push-rod assembly.

Fourier Transform Infrared Spectroscopy (FTIR) experiments were conducted in either a nitrogen-purged glovebox or directly in air using a Bruker Alpha FTIR spectrometer in DRIFTS mode or transmission mode. Spectra were collected by averaging 20 scans at 2 cm⁻¹ resolution.

Hydrouoric acid (HF) vapor etching (50% in water) of oxidized Si NCs was performed in a room-temperature container. The oxide was removed after exposing the Si NCs to the vapor for 2 to 4 hours. After etching, the samples were transferred air-free to a nitrogen purged glovebox for further analysis.

X-ray Photoelectron Spectroscopy (XPS) spectra were acquired on a Surface Science Laboratories, Inc. SSX-100 XPS with a monochromatic Al Kα X-ray source. A X-ray power of 200 W with a 1 mm² spot size was used. Si NC samples were prepared by directly impacting a <50 nm thin film of Si NCs onto a gold-coated Si wafer. B1s and P1p peaks were obtained by integrating scans for 2.5 hours. Peaks were assigned by using the C1s peak as a reference at 285 eV.

Electron Paramagnetic Resonance (EPR) measurements were taken using a Bruker Continuous Wave Elexsys E500 electron paramagnetic resonance spectrometer. For the measurements, a few milligrams of Si NC powder was pressed into the bottom of sample tubes (suprasil quartz), and the open end of the tubes was sealed with epoxy glue in order to enable their transport from the glovebox to the EPR spectrometer without exposing the NCs to air. The spectra were normalized to the weight of the nanoparticles.

X-ray Diffraction (XRD) from nanoparticles was collected using a Bruker-AXS Microdiffractometer with a 2.2 kW sealed Cu x-ray source. The nanoparticle diameter was calculated from the Scherrer equation.

Transmission Electron Microscope (TEM) images of the doped nanoparticles were collected on lacy-carbon grids and examined with a Tecnai G2 F30 transmission electron microscope.

The complete disclosure of all patents, patent applications, and publications, and electronically available material (e.g., GenBank amino acid and nucleotide sequence submissions; and protein data bank (pdb) submissions) cited herein are incorporated by reference. The foregoing detailed description and examples have been given for clarity of understanding only. No unnecessary limitations are to be understood therefrom. The invention is not limited to the exact details shown and described, for variations obvious to one skilled in the art will be included within the invention defined by the claims.

What is claimed is:

1. A Group IV nanocrystal having a surface substantially free of oxygen.

2. The Group IV nanocrystal of claim 1 wherein the surface of the nanocrystal is substantially free of organic ligands and surfactants.

3. The Group IV nanocrystal of claim 1 wherein the Group IV element is selected from the group consisting of Si, Ge, and combinations thereof.

4. The Group IV nanocrystal of claim 1 wherein the surface of the nanocrystal further comprises P and/or B atoms.

5. The Group IV nanocrystal of claim 1 wherein the surface of the nanocrystal comprises from 0 atom % to 100 atom % P atoms.

6. The Group IV nanocrystal of any claim 1 wherein the surface of the nanocrystal comprises from 0 atom % to 100 atom % B atoms.

7. The Group IV nanocrystal of claim 1 wherein the surface of the nanocrystal comprises from 1 atom % to 30 atom % B atoms.

8. The Group IV nanocrystal of claim 1 wherein the nanocrystal further comprises activated dopants in the silicon core and the nanocrystal has an infrared surface plasmon absorption.

9. A method of making a Group IV nanocrystal comprising:
providing a Group IV monomer and a phosphorus and/or boron precursor to a plasma reactor under conditions effective to produce a Group IV nanocrystal,
wherein the surface of the nanocrystal is substantially free of oxygen.

10. A nanocrystal ink comprising a colloidal dispersion of Group IV nanocrystals according to claim 1 in a solvent.

11. The nanocrystal ink of claim 10 wherein the concentration of Group IV nanocrystals in the ink is 1 microgram per milliliter to 1 gram per milliliter.

12. The nanocrystal ink of claim 10 wherein the solvent is an aqueous or non-aqueous solvent.

13. The nanocrystal ink of claim 10 wherein the solvent comprises at least one organic solvent that is a dipolar, organic solvent having a hard donor group, without a strongly acidic site, and does not chemically react with the nanocrystal surface.

14. The nanocrystal ink of claim 13 wherein the at least one organic solvent is selected from the group consisting of halogenated aromatics, ketones, esters, N-substituted pyrrolidinones, N,N-disubstituted amides, nitriles, and combinations thereof.

15. The nanocrystal ink of claim 13 wherein the solvent further comprises water.

16. The nanocrystal ink of claim 10 wherein the nanocrystals are substantially non-agglomerated.

17. A method of preparing a nanocrystal ink comprising combining a plurality of Group IV nanocrystals according to claim 1 with an organic solvent under conditions effective to form a colloidal dispersion of the nanocrystals.

18. The method of claim 17 wherein conditions effective comprise gentle mixing or sonication at room temperature.

19. A nanocrystal film comprising a plurality of Group IV nanocrystals according to claim 1.

20. A method of making a nanocrystal film comprising solution coating a nanocrystal ink according to claim 10.

21. The method of claim 20 wherein solution coating comprises a method selected from the group consisting of drop casting, spin coating, dip coating, meyer rod coating, doctor blade coating, inkjet printing, screen printing, contact printing, spray coating, and combinations thereof.

22. The method of claim 20 further comprising allowing the solvent to evaporate at a temperature of at most 250° C.

23. A semiconductor device comprising a nanocrystal film according to claim 19.

24. The semiconductor device of claim 23 wherein the device is a solar cell, a transistor, a photodetector, or a light emitting diode.
